(19) United States
(12) Patent Application Publication
(10) Pub. No.: US 2025/0234605 A1
(43) Pub. Date: Jul. 17, 2025

(54) SEMICONDUCTOR STRUCTURE AND METHOD FOR MANUFACTURING THE SAME

(71) Applicant: Taiwan Semiconductor Manufacturing Company, Ltd., Hsinchu (TW)

(72) Inventors: Ta-Chun LIN, Hsinchu (TW); Jhon-Jhy LIAW, Zhudong Township (TW)

(73) Assignee: Taiwan Semiconductor Manufacturing Company, Ltd., Hsinchu (TW)

(21) Appl. No.: 18/411,400

(22) Filed: Jan. 12, 2024

(51) Int. Cl. H01L 29/06; H01L 27/06; H01L 29/423; H01L 29/66; H01L 29/775; H01L 29/786

(52) U.S. Cl. CPC H10D 62/121; H10D 30/014; H10D 30/43; H10D 30/6735; H10D 30/6757; H10D 64/017; H10D 84/40

(57) ABSTRACT

A semiconductor structure includes a first transistor, a second transistor, and a gate structure. The first transistor includes first nanostructures and first source/drain features. The first nanostructures are spaced apart from each other in a Z-direction. The first source/drain features are on opposite sides of the first nanostructures in an X-direction. The second transistor includes second nanostructures and second source/drain features. The second nanostructures are spaced apart from each other in the Z-direction. The second nanostructures are over the first nanostructures. The second source/drain features are on opposite sides of the second nanostructures in the X-direction. The second source/drain features are over the first source/drain features. The gate structure wraps around the first nanostructures and the second nanostructures. A thickness of middle portions of the first nanostructures is greater than a thickness of middle portions of the second nanostructures.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) devices have been incorporated into memory devices (including, for example, static random-access memory, or SRAM, cells) and core devices (including, for example, standard logic, or STD, cells) to reduce the chip footprint while maintaining reasonable processing margins.

As GAA devices continue to be developed, complementary metal-oxide-semiconductor field effect transistors (CMOSFET or CFET) has been provided due to their high noise immunity and low static power consumption. However, although existing technologies for fabricating CFETs have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is an X-Z cross-sectional view of a semiconductor device, in accordance with some embodiments of the present disclosure.

FIG. 1B is a Y-Z cross-sectional view of the semiconductor device along a line B-B′ of FIG. 1A, in accordance with some embodiments of the present disclosure.

FIG. 1C is a Y-Z cross-sectional view of the semiconductor device along a line C-C′ of FIG. 1A, in accordance with some embodiments of the present disclosure.

FIG. 1D is an X-Y cross-sectional view of the semiconductor device along a line D-D′ of FIG. 1A, in accordance with some embodiments of the present disclosure.

FIG. 1E is an X-Y cross-sectional view of the semiconductor device along a line E-E′ of FIG. 1A, in accordance with some embodiments of the present disclosure.

FIGS. 2, 3, 4, 5 and 6 are X-Z cross-sectional views of the semiconductor device, in accordance with some alternative embodiments of the present disclosure.

FIG. 7 is a Y-Z cross-sectional view of the semiconductor device, in accordance with some alternative embodiments of the present disclosure.

FIG. 8 is a perspective view of a workpiece at a fabrication stage, in accordance with some embodiments of the present disclosure.

FIGS. 9, 10, 11B, 21B, 22B, 23B, and 24B are Y-Z cross-sectional views of the workpiece at various fabrication stages along a line F-F′ of FIG. 8, in accordance with some embodiments of the present disclosure.

FIGS. 11A, 12A, 13A, 14A, 15A, 16A, 17A, 18A, 19A, and 20A are Y-Z cross-sectional views of the workpiece at various fabrication stages along a line G-G′ of FIG. 8, in accordance with some embodiments of the present disclosure.

FIGS. 12B, 13B, 14B, 15B, 16B, 17B, 18B, 19B, 20B, 21A, 22A, 23A, and 24A are Y-Z cross-sectional views of the workpiece at various fabrication stages along a line H-H′ of FIG. 8, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to field-effect transistors (FETs), such as three-dimensional complementary field effect transistors (CFETs) with gate-all-around (GAA) structures, in memory (e.g., SRAM) and/or standard logic cells of an integrated circuit (IC) structure. Generally, a CFET may include a n-type FET (NFET) and a p-type FET (PFET) disposed vertically with a plurality of vertically stacked sheets (e.g., nanosheets), wires (e.g., nanowires), or rods (e.g., nanorods) in a channel region of the CFET, thereby allowing better gate control, lowered leakage current, and improved scaling capability for various IC applications. While existing technologies for fabricating CFETs have been generally adequate for their intended applications, they have not been entirely satisfactory in all aspects.

The gate-all-around (GAA) structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures including NFET with thinner nanostructures and PFET with thicker nanostructures in the CFET to enhance performance. The details of the structure and fabrication methods of the present disclosure are described below in conjunction with the accompanying drawings, which illustrate the processes and the structures for CFET, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated.

The circuit cells and the SRAM cells may be constructed by transistors. The transistors may be planar transistors, fin field-effect transistor (FinFET) transistors, gate-all-around (GAA) transistors, nano-wire transistors, nano-sheet transistors, CFETs, or a combination thereof. In the present disclosure, an exemplary semiconductor device with CFETs is illustrated in below. However, it should be understood that the application should not be limited to a particular type of device, except as specifically claimed.

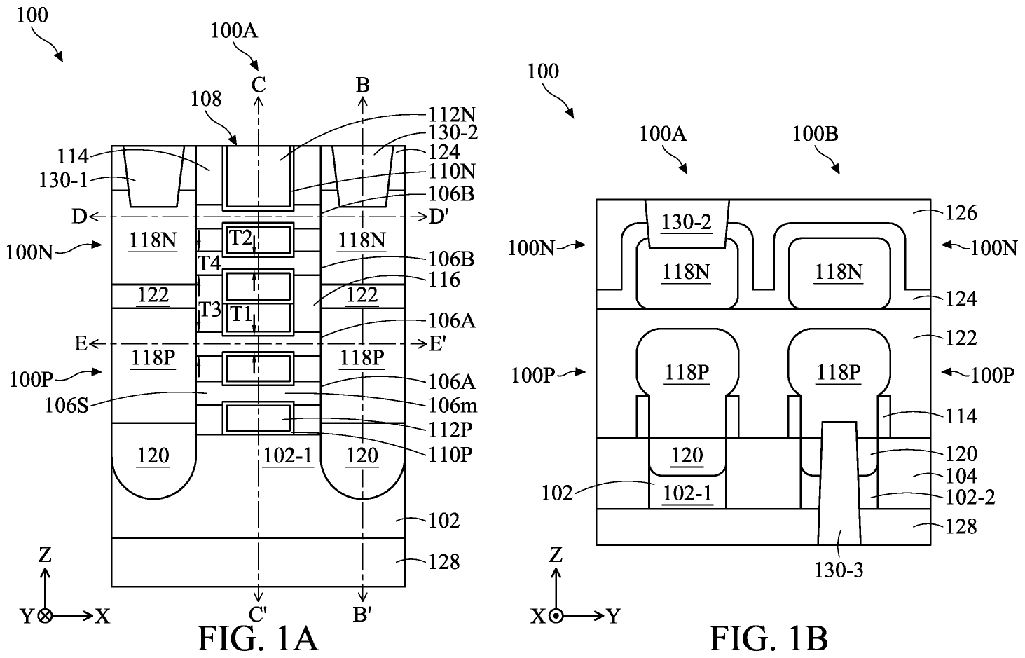

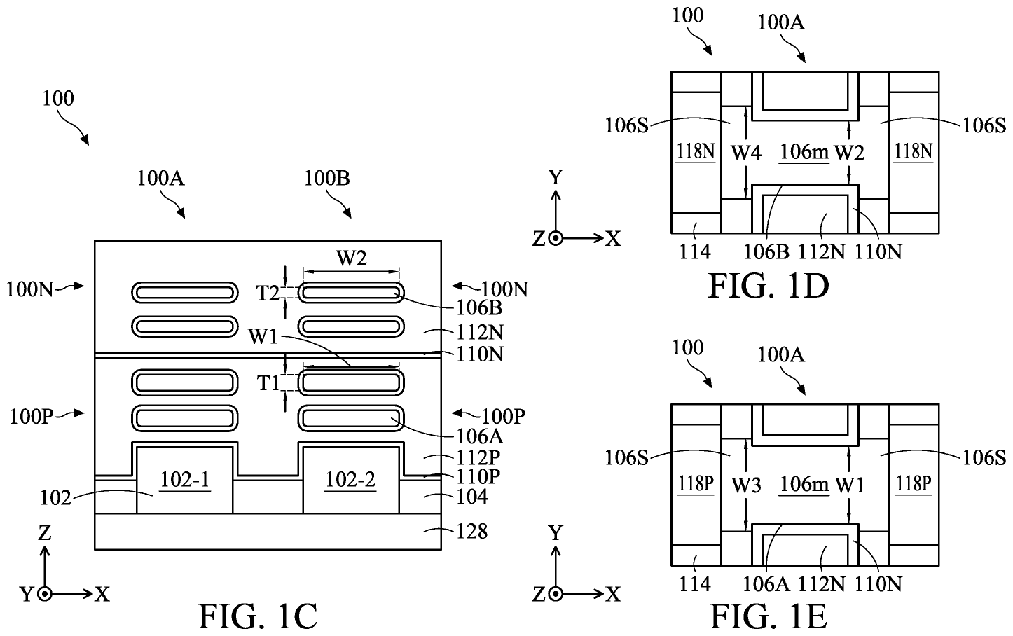

FIG. 1A is an X-Z cross-sectional view of a semiconductor device 100, in accordance with some embodiments of the present disclosure. FIG. 1B is a Y-Z cross-sectional view of the semiconductor device 100 along a line B-B′ of FIG. 1A, in accordance with some embodiments of the present disclosure. FIG. 1C is a Y-Z cross-sectional view of the semiconductor device 100 along a line C-C′ of FIG. 1A, in accordance with some embodiments of the present disclosure. FIG. 1D is an X-Y cross-sectional view of the semiconductor device 100 along a line D-D′ of FIG. 1A, in accordance with some embodiments of the present disclosure. FIG. 1E is an X-Y cross-sectional view of the semiconductor device 100 along a line E-E′ of FIG. 1A, in accordance with some embodiments of the present disclosure.

Referring to FIGS. 1A to 1R, the semiconductor device 100 includes two complementary field effect transistors (CFETs) 100A and 100B. The CFETs 100A and 100B arranged in the Y-direction, as shown in FIGS. 1B and 1C. The CFETs 100A and 100B have similar structure and features. Furthermore, each of the CFETs 100A and 100B has a p-type field effect transistor (PFET) 100P and an n-type field effect transistors (NFET) 100N. In each of the CFETs 100A and 100B, the NFET 100N is disposed over the PFET 100P in the Z-direction, as shown in FIGS. 1A to 1C.

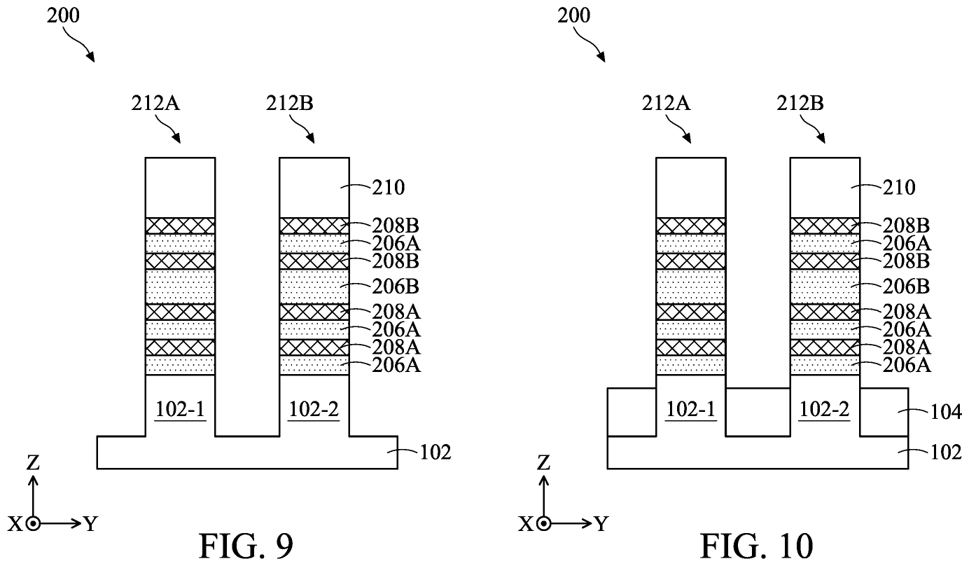

The semiconductor device 100 further includes a substrate 102, as shown in FIG. 1A to 1C. The substrate 102 includes a base portion 102-1 for the CFET 100A and a base portion 102-1 for the CFET 100A, which protruded from the substrate 102 under the nanostructures 106A and 106B (not shown in FIGS. 1A to 1C, may refer to FIG. 9). Subsequent features for the CFETs 100A and 100B are formed over the base portions 102-1 and 102-2 of the substrate 102, as described in further detail below. In some embodiments, after the resultant NFETs 100N and PFETs 100P of the CFETs 100A and 100B are formed, a portion of the substrate 102 may be removed by a suitable process (e.g., a chemical mechanical polishing (CMP) process) for forming back-side interconnection, remaining the base portions 102-1 and 102-2.

In some embodiments, the substrate 102 contains a semiconductor material, such as bulk silicon (Si). In some other embodiments, the substrate 102 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 102 may also include an insulating layer, such as a silicon oxide layer, to have a silicon-on-insulator (SOI) structure or a germanium-on-insulator (GOI) structure.

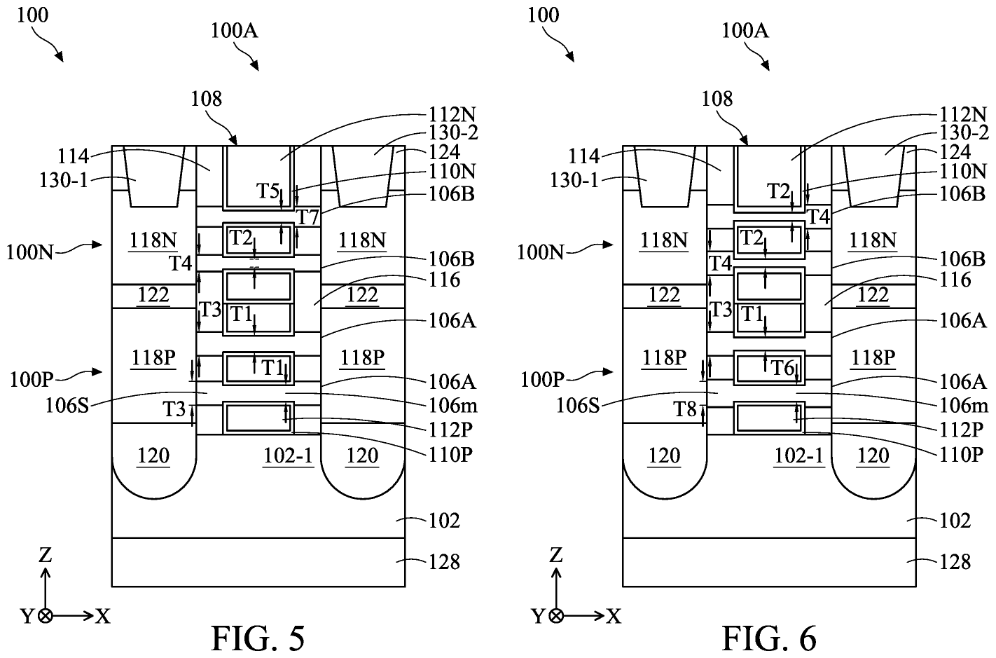

The semiconductor device 100 further includes an isolation feature (or isolation structure) 104 over the substrate 102. The isolation feature 104 is also formed between the base portions 102-1 and 102-2 of the substrate 102, as shown in FIG. 5C. In some embodiments, top surfaces of the isolation feature 104 are lower than top surfaces of the substrate 102 (more specifically, top surfaces of the base portions 102-1 and 102-2). The isolation feature 104 may include silicon oxide, silicon nitride, silicon oxynitride, other suitable isolation material (for example, including silicon, oxygen, nitrogen, carbon, or other suitable isolation constituent), or combinations thereof. The isolation feature 308 may include different structures, such as shallow trench isolation (STI) structures, deep trench isolation (DTI) structures, and/or local oxidation of silicon (LOCOS) structures. In some embodiments, STI features include a multi-layer structure that fills the trenches, such as a silicon nitride comprising layer disposed over a thermal oxide comprising liner layer. In another example, STI features include a dielectric layer disposed over a doped liner layer (including, for example, boron silicate glass (BSG) or phosphosilicate glass (PSG)). In yet another example, STI features include a bulk dielectric layer disposed over a liner dielectric layer, where the bulk dielectric layer and the liner dielectric layer include materials depending on design requirements.

Referring to FIGS. 1A to 1E, the semiconductor device 100 further includes two groups of nanostructures, such as nanostructures 106A and nanostructures 106B (may be collectively referred to as the nanostructures 106). In some embodiments, the nanostructures 106 may also be referred to as channels, channel layers, nanosheets, or nanowires. The nanostructures 106B are disposed over the nanostructures 106A, as shown in FIGS. 1A and 1C. The nanostructures 106A are used for the PFETs in the CFETs and the nanostructures 106B are used for the NFETs in the CFETs.

Furthermore, the nanostructures 106 are suspended over the base portions 102-1 and 102-2 of the substrate 102. In some embodiments, the nanostructures 106 extend in the X-direction and vertically stacked (or arranged) in the Z-direction. More specifically, the nanostructures 106A are spaced apart from each other in the Z-direction, the nanostructures 106B are spaced apart from each other in the Z-direction, and the nanostructures 106B are over and spaced apart from the nanostructures 106A. As shown in FIGS. 1A and 1C, a distance between the nanostructures 106A and nanostructures 106B (i.e., a distance between a topmost nanostructure 106A and a bottommost nanostructure 106B) is greater than a distance between two nanostructures 106A or between two nanostructures 106B.

In some embodiments, two nanostructures 106 are vertically stacked (or vertically arranged) from each other in the Z-direction for one transistor. For example, as shown in FIG. 1A, in one CFET 100A, the NFET 100N has two nanostructures 106 vertically stacked from each other in the Z-direction and the PFET has two nanostructures 106 vertically stacked from each other in the Z-direction. However, there may be another appropriate number of nanostructures in one transistor. For example, there may be 1, 2, 3, 4, or more than 4 nanostructures 310 in one transistor.

Furthermore, the nanostructures 106 further extend lengthwise in the X-direction (FIGS. 1A, 1D, and 1E) and widthwise in the Y-direction (FIGS. 1C to 1E). Each of the nanostructures 106 has a middle portion 106m and two side portions 106s. The side portions 106s are disposed on opposite sides of the nanostructures 106 in the X-direction, as shown in FIGS. 1A, 1D, and 1E. More specifically, two side portions 106s are attached to two ends of the middle portion 106m in one nanostructure 106 in the X-direction. In some embodiments, the thickness of each of the side portions 106s in the Z-direction is greater than the thickness of each of the middle portions 106m in the Z-direction. Furthermore, a width of each of the side portions 106s is greater than a width of each of the middle portions 106m. As such, each of the nanostructures 106A in the PFETs 100P and the nanostructures 106B in the NFETs 100N has a dumbbell-shape in the X-Z cross-sectional view, as shown in FIG. 1A. Furthermore, in some embodiments, each of the nanostructures 106A in the PFETs 100P and the nanostructures 106B in the NFETs 100N also has a dumbbell-shape in the X-Y cross-sectional view, as shown in FIGS. 1D and 1E.

In the present disclosure, the thickness of the nanostructures 106A in the PFETs 100P is greater than the thickness of the nanostructures 106B in the NFETs 100N for improving the performance of the CFETs 100A and 100B. More specifically, the thickness T1 of the middle portions 106m of the nanostructures 106A in the PFETs 100P is greater than the thickness T2 of the middle portions 106m of the nanostructures 106B in the NFETs 100N, as shown in FIGS. 1A, 1C, 1D, and 1E. In some embodiments, a difference between the thickness T1 of the middle portions 106m of the nanostructures 106A in the PFETs 100P and the thickness T2 of the middle portions 106m of the nanostructures 106B in the NFETs 100N (i.e., T1−T2) is in a range from about 0.5 nm to about 5 nm.

Furthermore, the thickness T3 of the side portions 106s of the nanostructures 106A in the PFETs 100P and the thickness T4 of the side portions 106s of the nanostructures 106B in the NFETs 100N are the same, as shown in FIG. 1A. As such, a difference between the thickness T3 of the side portions 106s of the nanostructures 106A and the thickness T1 of the middle portions 106m of the nanostructures 106A (i.e., T3−T1) is smaller than a difference between the thickness T4 of the side portions 106s of the nanostructures 106B and the thickness T2 of the middle portions 106m of the nanostructures 106B (i.e., T4−T2). In other words, the thickness T3 of the side portions 106s of the nanostructures 106A minus the thickness T1 of the middle portions 106m of the nanostructures 106A (i.e., T3−T1) is smaller than the thickness T4 of the side portions 106s of the nanostructures 106B minus the thickness T2 of the middle portions 106m of the nanostructures 106B (i.e., T4−T2). In some embodiments, a difference between the difference between the thickness T3 of the side portions 106s of the nanostructures 106A and the thickness T1 of the middle portions 106m of the nanostructures 106A and the difference between the thickness T4 of the side portions 106s of the nanostructures 106B and the thickness T2 of the middle portions 106m of the nanostructures 106B (i.e., (T3−T1)-(T4−T2)) is in a range from about 0.5 nm to about 5 nm.

In the present disclosure, the width of the nanostructures 106A in the PFETs 100P is also greater than the width of the nanostructures 106B in the NFETs 100N for improving the performance of the CFETs 100A and 100B, in accordance with some embodiments. More specifically, the width W1 of the middle portions 106m of the nanostructures 106A in the PFETs 100P is greater than the width W2 of the middle portions 106m of the nanostructures 106B in the NFETs 100N, as shown in FIGS. 1C, 1D, and 1E. In some embodiments, a difference between the width W1 of the middle portions 106m of the nanostructures 106A in the PFETs 100P and the width W2 of the middle portions 106m of the nanostructures 106B in the NFETs 100N (i.e., W1−W2) is in a range from about 0.5 nm to about 5 nm.

Furthermore, the width W3 of the side portions 106s of the nanostructures 106A in the PFETs 100P and the width W4 of the side portions 106s of the nanostructures 106B in the NFETs 100N are the same, as shown in FIGS. 1D and 1E. As such, similarly, a difference between the width W3 of the side portions 106s of the nanostructures 106A and the width W1 of the middle portions 106m of the nanostructures 106A (i.e., W3−W1) is smaller than a difference between the width W4 of the side portions 106s of the nanostructures 106B and the width W2 of the middle portions 106m of the nanostructures 106B (i.e., W4−W2). In other words, the width W3 of the side portions 106s of the nanostructures 106A minus the width W1 of the middle portions 106m of the nanostructures 106A (i.e., W3−W1) is smaller than the width W4 of the side portions 106s of the nanostructures 106B minus the width W2 of the middle portions 106m of the nanostructures 106B (i.e., W4−W2). In some embodiments, a difference between the difference between the width W3 of the side portions 106s of the nanostructures 106A and the width W1 of the middle portions 106m of the nanostructures 106A and the difference between the width W4 of the side portions 106s of the nanostructures 106B and the width W2 of the middle portions 106m of the nanostructures 106B (i.e., (W3−W1)-(W4−W2)) is in a range from about 0.5 nm to about 5 nm.

In the CFETs 100A and 100B, the NFETs 100N prefer thinner and/or narrower (middle portion) nanostructures 106B for gate control and the PFETs 100P prefer thinner and/or narrower (middle portion) nanostructures 106B for better mobility and higher on-current. Therefore, according to above discussion, each of the CFETs 100A and 100B has one NFET 100N with thinner and/or narrower (middle portion) nanostructures 106B and one PFET 100P with thinner and/or wider (middle portion) nanostructures 106A, such that the NFETs 100N have better gate control and the PFETs 100P have better mobility and higher on-current, thereby improving the performance of the CFETs 100A and 100B. As discussed above, the difference between the thickness T1/the width W1 of the middle portions 106m of the nanostructures 106A in the PFETs 100P and the thickness T2/the width W2 of the middle portions 106m of the nanostructures 106B in the NFETs 100N (i.e., T1−T2 and/or W1−W2) is in a range from about 0.5 nm to about 5 nm. If the difference is too small (less than about 0.5 nm), the thickness/width of the nanostructures 106B in the NFETs 100N are too large or the thickness/width of the nanostructures 106A in the PFETs 100P are too small, such that the NFETs 100N have worse gate control and/or the PFETs 100P have worse mobility and lower on-current. If the difference is too large (greater than about 5 nm), the thickness/width of the nanostructures 106B in the NFETs 100N are too small or the thickness/width of the nanostructures 106A in the PFETs 100P are too large, such that the NFETs 100N have worse mobility and lower on-current and/or the PFETs 100P have worse gate control. It is need a trade-off in the difference between the thicknesses and/or widths of the nanostructures 106A and 106B in the PFET 100P and NFET 100N.

The nanostructures 106A and 106B may include a semiconductor material, such as silicon, germanium, silicon carbide, silicon phosphide, gallium arsenide, gallium phosphide, indium phosphide, indium arsenide, and/or indium antimonide, silicon germanium (SiGe), SiPC, GaAsP, AlInAs, AlGaAs, GalnAs, GalnP, and/or GaInAsP. In some embodiments, the nanostructures 106 include silicon for N-type transistors (i.e., NFETs 100N of the CFETs 100A and 100B). In other embodiments, the nanostructures 106 include silicon germanium for P-type transistors (i.e., PFETs 100P of the CFETs 100A and 100B). In some embodiments, the nanostructures 106 are all made of silicon, and the type of the transistors depend on a work function metal layer wrapping around the nanostructures 106. In some embodiments, the nanostructures 106 are epitaxially grown using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized.

Referring to FIGS. 1A to 1E, the semiconductor device 100 further includes a gate structure 108 wrapping around the nanostructures 106. More specifically, the gate structure 108 wrap around the nanostructures 106A in the PFETs 100P and the nanostructures 106B in the NFETs 100N. The CFETs 100A and 100B share the gate structure 108. More specifically, the gate structure 108 extend in the Y-direction to wrap around the nanostructures 106 in the CFET 100A and the nanostructures 106 in the CFET 100B, as shown in FIG. 1C.

The gate structure 108 has a gate dielectric layer 110P, a gate electrode layer 112P, a gate dielectric layer 110N, and a gate electrode layer 112N (the gate dielectric layer 110P and 110N may be collectively referred to as the gate dielectric layer 110, and the gate electrode layer 112P and 112N may be collectively referred to as the gate electrode layer 112). As shown in FIGS. 1A and 1C to 1E, the gate dielectric layer 110P wrap around each of the nanostructures 106A in the PFETs 100P and the gate dielectric layer 110N wrap around each of the nanostructures 106N in the NFETs 100N. The gate electrode layer 112P wrap around the gate dielectric layer 110P and each of the nanostructures 106A in the PFETs 100P and the gate electrode layer 112N wrap around the gate dielectric layer 110N and each of the nanostructures 106N in the NFETs 100N.

Furthermore, the gate dielectric layer 110P is also formed on the top surfaces of the isolation feature 104 and the top surfaces and sidewalls of the substrate 102 (more specifically, the top surfaces and sidewalls of the base portions 102-1 and 102-2), as shown in FIGS. 1A and 1C. The gate dielectric layer 110N is also formed on a top surface of the gate electrode layer 112P, as shown in FIGS. 1A and 1C. In some embodiments, the gate dielectric layer 110P is further formed on sidewalls of inner spacers 116 (discussed in below) and the gate dielectric layer 110N is further formed on sidewalls of the gate spacer 114 (discussed in below) and the inner spacers 116, as shown in FIGS. 1A, 1D, and 1E. Furthermore, as shown in FIG. 1A, the gate dielectric layer 110P is in contact with the gate dielectric layer 110N, as shown in FIG. 1A.

In some embodiments, the gate structure 108 further includes an interfacial layer (such as having silicon dioxide, silicon oxynitride, or other suitable materials) between the gate dielectric layer 110 and the nanostructures 106. The gate dielectric layers 110P and 110N may include oxide with nitrogen doped dielectric material (initial layer) combined with metal content high-K dielectric material (K value (dielectric constant)>13). For example, the gate dielectric layers 110P and 110N may include hafnium oxide (HfO₂), which has a dielectric constant in a range from about 18 to about 40. Alternatively, the gate dielectric layers 110P and 110N may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr) TiO₃ (BST), Al₂O₃, Si₃N₄, oxynitrides (SiON), combinations thereof, or other suitable material. The gate dielectric layers 110P and 110N may be formed by chemical oxidation, thermal oxidation, ALD, CVD, and/or other suitable methods.

As discussed above, the gate electrode layer 112P and 112N is formed to wrap around the gate dielectric layer 110P and 110N and the middle portions of the nanostructures 106, as shown in FIGS. 1A and 1C to 1E. In some embodiments, the gate electrode layer 112P may include one or more P-type work function metal layers for PFETs 100P and the gate electrode layer 112N may include one or more N-type work function metal layers for NFETs 100N. Therefore, the gate dielectric layers 110P and 110N may be referred to as work function metal layers.

The N-type work function metal layers and the P-type work function metal layers may be selected from a group consisting of TiN, TaN, TiAl, TiAlN, TaAl, TaAlN, TaAlC, TaCN, WNC, Co, Ni, Pt, W, or a combination thereof, in accordance with some embodiments. The material of the N-type work function metal layers and the P-type work function metal may layers be the same. In some embodiments, the material of the N-type work function metal layers and the P-type work function metal layers are different.

In some embodiments, the N-type work function metal layers include a material such as Ti, Al, Ag, Mn, Zr, TiAl, TiAlC, TaC, TaCN, TaSiN, TaAl, TaAlC, TiAlN, other suitable N-type work function materials, or combinations thereof. For example, the N-type work function metal layer may be deposited utilizing ALD, CVD, or the like. However, any suitable materials and processes may be utilized to form the N-type work function metal layer 314N.

In some embodiments, the P-type work function metal layers include a material such as TiN, TaN, Ru, Mo, Al, WN, ZrSi₂, MoSi₂, TaSi₂, NiSi₂, other metal oxides, metal nitrides, metal silicates, transition metal-oxides, transition metal-nitrides, transition metal-silicates, oxynitrides of metals, metal aluminates, zirconium silicate, zirconium aluminate, other suitable P-type work function materials, combinations of these, or the like. Additionally, the P-type work function metal layer 314P may be deposited using a deposition process such as ALD, CVD, or the like, although any suitable deposition process may be used.

In some embodiments, each of the gate electrode layers 112P and 112N may include a single layer or alternatively a multi-layer structure. In some embodiments, the gate electrode layer 112P and 112N may further include a capping layer, a barrier layer, and a fill material (not shown). The capping layer may be formed adjacent to the gate dielectric layers 112P and 112N and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as ALD, CVD, or the like, although any suitable deposition process may be used. The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The semiconductor device 100 further include gate spacers 114 on opposite sides of the gate structure 108. More specifically, the gate spacers 114 are on sidewalls of the gate structures 108 and over the nanostructures 106, as shown in FIG. 1A. Furthermore, as shown in FIG. 1A, the gate spacers 114 are over and on (top surfaces of) the side portions 106s of the (topmost) nanostructures 106B, in accordance with some embodiments. In some embodiments, the gate spacers 114 on sidewalls of the side portions 106s of the nanostructures 106A and 106B, as shown in FIGS. 1D and 1E. The gate spacers 114 are over the nanostructures 106 and on top sidewalls of the gate structures 108, and thus are also referred to as gate top spacers or top spacers.

The gate spacers 114 may include multiple dielectric materials and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof. In some embodiments, the gate spacers 114 may include a single layer or a multi-layer structure.

As shown in FIG. 1A, the semiconductor device 100 further includes inner spacers 116 on opposite sides of the gate structure 108. More specifically, the inner spacers 116 are on the sidewalls of the gate structure 108, and below the gate spacers 114 and the topmost nanostructure 106B. As shown in FIG. 1A, the inner spacers 320 are also vertically between (the side portions 106s of) adjacent nanostructures 106B, vertically between (the side portions 106s of) adjacent nanostructures 106B and 106A, vertically between (the side portions 106s of) adjacent nanostructures 106A, and vertically between (bottommost) nanostructures 106A and the substrate 102, in accordance with some embodiments. In some embodiments, a thickness of the inner spacers 116 vertically between adjacent nanostructures 106B and 106A in the Z-direction is greater than thicknesses of other inner spacers 116, as shown in FIG. 1A. Furthermore, the inner spacers 116 are laterally between the source/drain features 118N/118P and the gate structure 108 in the Z-direction.

The inner spacers 116 may include a dielectric material having higher K value (dielectric constant) than the gate spacers 114 and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), air gap, or a combination thereof. In other embodiments, the inner spacers 116 may include a dielectric material having lower K value (dielectric constant) than the gate spacers 114.

In some embodiments, the thickness of the gate spacers 114 in the X-direction and the thickness of the inner spacers 116 in the X-direction are the same. In other embodiments, the thickness of the gate spacers 114 in the X-direction is greater than the thickness of the inner spacers 116 in the X-direction for capacitance reduction between source/drain contact 118N/118P and the gate structure 108.

Referring to FIGS. 1A, 1B, 1D, and 1E, each of the NFETs 100N and PFETs 100P in the semiconductor device 100 further includes source/drain features 118N and source/drain features 118P over the substrate 102. More specifically, the source/drain features 118P are disposed over the substrate 102 and the source/drain features 118N are disposed over the source/drain features 118P. In some embodiments, the source/drain features 118N are vertically separated from the source/drain features 118P in the Z-direction, as shown in FIGS. 1A and 1B. As shown in FIGS. 1A, 1D, and 1E, the source/drain features 118N are disposed on opposite sides of the gate structure 108 in the X-direction to form the NFETs 100N. Similarly, the source/drain features 118P are disposed on opposite sides of the gate structure 108 in the X-direction to form the PFETs 100P.

The nanostructures 106 extend in the X-direction to connect one source/drain feature 118N/118P to the other source/drain feature 118N/118P. More specifically, the source/drain features 118P are disposed on opposite sides of the nanostructures 106A in the X-direction and the source/drain features 118N are disposed on opposite sides of the nanostructures 106B in the X-direction. Therefore, the source/drain features 118P are attached and electrically connected to the nanostructures 106A in the X-direction and the source/drain features 118N are attached and electrically connected to the nanostructures 106B in the X-direction. The source/drain features 118N/118P may also be referred to as source/drain, or source/drain regions. In some embodiments, source/drain feature(s) may refer to a source or a drain, individually or collectively dependent upon the context.

The source/drain features 118N may be formed by using epitaxial growth. In some embodiments, the source/drain features 118N may include epitaxially-grown material selected from a group consisting of SiP, SiC, SiPC, SiAs, Si, or a combination thereof. In some embodiments, the epitaxially-grown material of the source/drain features 118N may be doped with N-type dopants (such as phosphorus, arsenic, other N-type dopant, or a combination thereof) having a doping concentration in a range from about 2×10¹⁹/cm³ to 3×10²¹/cm³. In some embodiments, the source/drain features 118N for N-type transistors may respectively be referred to as N-type features and N-type source/drain features.

In some embodiments, the source/drain features 118P may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 118P may be doped with P-type dopants (such as boron, indium, other P-type dopant, or a combination thereof) having a doping concentration in a range from about 1×10¹⁹/cm³ to 6×10²⁰/cm³. In some embodiments, the source/drain features 118P for P-type transistors may respectively be referred to as P-type source/drain features.

Referring to FIGS. 1A and 1B, the semiconductor device 100 further includes bottom dielectric layers 120 under the source/drain features 118N and 118P and over the substrate 102. More specifically, the bottom dielectric layers 120 are vertically between and in contact with the source/drain features 118P and the substrate 102 in the Z-direction. In some embodiments, top surfaces of the bottom dielectric layers 120 are higher than bottommost surfaces of the gate structure 108, as shown in FIG. 1A. In some aspects, the top surfaces of the bottom dielectric layers 120 are higher than topmost surfaces of the substrate 102 (i.e., the top surfaces of the base portions 102-1 and 102-2) to ensure that the bottom dielectric layers 120 separate the source/drain features 118P from the substrate 102.

In some embodiments, the dielectric material of the bottom dielectric layers 120 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), other suitable material(s), or combinations thereof, and may be deposited by CVD, PVD, ALD, HDPCVD, MOCVD, RPCVD, PECVD, LPCVD, ALCVD, APCVD, other suitable methods, or combinations thereof. It should be noted that the source/drain features 118P are separated from the substrate 102 by the bottom dielectric layers 120. As such, it prevents the leakage current of the resultant semiconductor device 100 (more specifically, CFETs 100A and 100B) from one source/drain feature 118P to another source/drain feature 118P through the substrate 102, thereby improving performances of the resultant semiconductor device 100.

Referring to FIGS. 1A and 1B, the semiconductor device 100 further includes an interlayer dielectric (ILD) layer 122 over the substrate 102, the isolation feature 104, and the source/drain features 118P. In some embodiments, the ILD layer 122 is also between and fill the spaces between the source/drain features 118P in the Y-direction, as shown in FIG. 1B. Furthermore, the ILD layer 122 is vertically between an in contact with the source/drain features 118P and the source/drain features 118N in the Z-direction. Therefore, the source/drain features 118P is separated and electrically isolated from the source/drain features 118N by the ILD layer 122.

The ILD layer 122 may comprise tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD layer 122 may be formed by PECVD (plasma enhanced CVD), FCVD (flowable CVD), or other suitable methods.

Referring to FIGS. 1A and 1B, the semiconductor device 100 further includes contact etch stop layers (CESLs) 124 over the source/drain features 118N and the ILD layer 122 and an interlayer dielectric (ILD) layer 126 over the CESLs 124 are formed to fill the space between the source/drain features 118N. More specifically, the CESLs 124 are conformally formed on the sidewalls of the gate spacers 114. In some embodiments, the CESLs 124 are also conformally formed on the top surfaces and the sidewalls of the source/drain features 118N, as shown in FIG. 1B. The ILD layer 126 is formed over and between the CESLs 124 to fill the space in the CESLs 124 and between the gate spacers 114.

The CESLs 124 include a material that is different than ILD layer 126. The CESLs 124 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods. The ILD layer 126 may comprise tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD layer 126 may be formed by PECVD (plasma enhanced CVD), FCVD (flowable CVD), or other suitable methods.

Referring to FIGS. 1A to 1C, the semiconductor device 100 further includes a dielectric layer 128 under the substrate 102. The dielectric layer 128 includes a dielectric material nitride, such as Si₃N₄, SiO₂, SiC, SiOC, SiON, SiCN, SiOCN, carbon doped oxide, nitrogen doped oxide, porous oxide, or combinations thereof. Referring to FIGS. 1A and 1B, the semiconductor device 100 further includes source/drain contacts 130, including source/drain contacts 130-1, 130-2, and 130-3, in accordance with some embodiments. The source/drain contacts 130-1 and 130-2 pass through the ILD layer 126, the CESLs 124, and portions of the source/drain features 118N to be in contact with and electrically connected to the source/drain features 118N, as shown in FIGS. 1A and 1B. Furthermore, the source/drain contact 130-3 pass through the dielectric layer 128, the substrate 102, and a portion of the source/drain feature 118P to be in contact with and electrically connected to the source/drain features 118P.

The source/drain contacts 130 may each include a conductive material such as Al, Cu, W, Co, Ti, Ta, Ru, Rh, Ir, Pt, Mo, TiN, TiAl, TiAlN, TaN, TaC, combinations of these, or the like, although any suitable material may be deposited using a deposition process such as sputtering, CVD, electroplating, electroless plating, or the like. In some embodiments, the source/drain contacts 130 may each include single conductive material layer or multiple conductive layers.

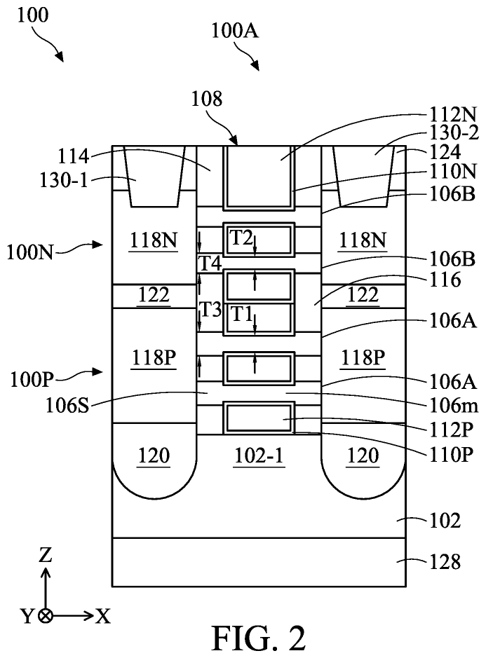

FIG. 2 is X-Z cross-sectional views of the semiconductor device 300, in accordance with some alternative embodiments of the present disclosure. The semiconductor device 100 shown in FIG. 2 is similar to the semiconductor device 100 shown in FIG. 2, except that the thickness T3 of the side portions 106s of the nanostructures 106A in the PFETs 100P and the thickness T4 of the side portions 106s of the nanostructures 106B in the NFETs 100N are different. As shown in FIG. 2, the thickness T3 of the side portions 106s of the nanostructures 106A in the PFETs 100P is greater than the thickness T4 of the side portions 106s of the nanostructures 106B in the NFETs 100N. However, the difference between the thickness T3 of the side portions 106s of the nanostructures 106A and the thickness T1 of the middle portions 106m of the nanostructures 106A (i.e., T3−T1) is still smaller than the difference between the thickness T4 of the side portions 106s of the nanostructures 106B and the thickness T2 of the middle portions 106m of the nanostructures 106B (i.e., T4−T2), similar to the discussion in FIGS. 1A to 1E. In other words, similarly, the thickness T3 of the side portions 106s of the nanostructures 106A minus the thickness T1 of the middle portions 106m of the nanostructures 106A (i.e., T3−T1) is smaller than the thickness T4 of the side portions 106s of the nanostructures 106B minus the thickness T2 of the middle portions 106m of the nanostructures 106B (i.e., T4−T2). In some embodiments, the difference between the difference between the thickness T3 of the side portions 106s of the nanostructures 106A and the thickness T1 of the middle portions 106m of the nanostructures 106A and the difference between the thickness T4 of the side portions 106s of the nanostructures 106B and the thickness T2 of the middle portions 106m of the nanostructures 106B (i.e., (T3−T1)-(T4−T2)) is also in a range from about 0.5 nm to about 5 nm.

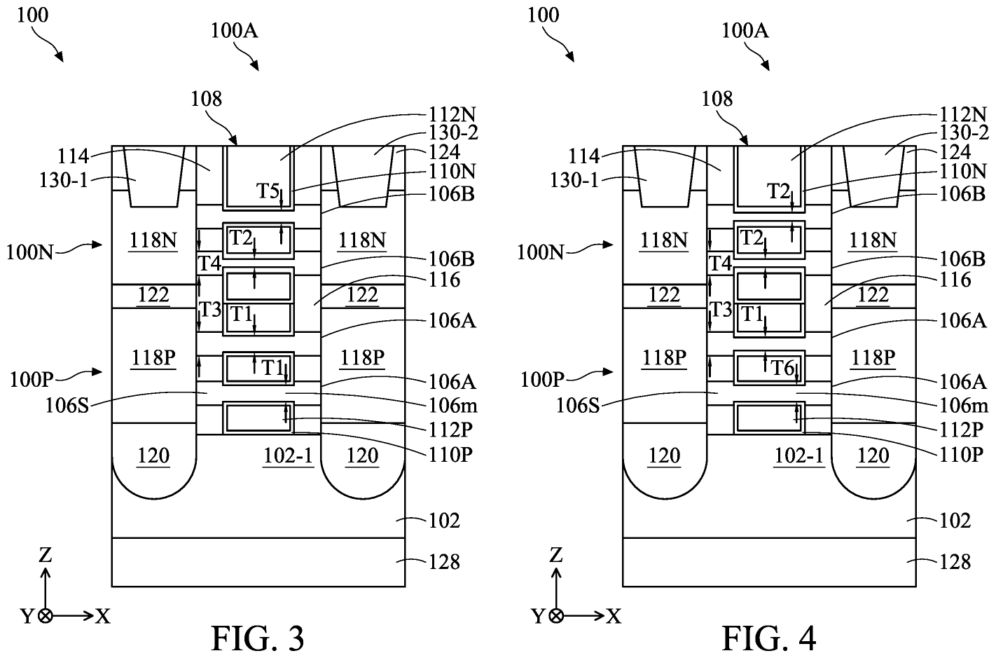

FIGS. 3 and 4 are X-Z cross-sectional views of the semiconductor device 300, in accordance with some alternative embodiments of the present disclosure. Referring back to FIG. 1A, the middle portions 106m of the nanostructures 106A in the PFETs 100P have the thickness T1 and the middle portions 106m of the nanostructures 106B in the NFETs 100N have the thickness T2, in which the thickness T1 is greater than the thickness T2. In FIG. 3, the middle portion 106m of the topmost nanostructure 106B in the NFET 100N in the CFET 100A have the thickness T5 greater than the thickness T2 of the middle portion 106m of the other nanostructure 106B in the NFET 100N. In the present embodiments, the side portions 106s of the topmost nanostructure 106B in the NFET 100N also have the thickness T4. The thickness T1 of the middle portions 106m of the nanostructures 106A in the PFET 100P is still greater than the thickness T5 of the middle portions 106m of the topmost nanostructure 106B in the NFET 100N. In some embodiments, a difference between the thickness T5 of the middle portion 106m of the topmost nanostructure 106B in the NFET 100N and the thickness T2 of the middle portion 106m of the other nanostructure 106B in the NFET 100N (i.e., T5−T2) is in a range from about 0.5 nm to about 3 nm. Such structure is due to that the topmost nanostructure 106B in the NFET 100N in the CFET 100A is closest to the source/drain contacts 130-1 and 130-2 over and in contact with the source/drain features 118N, so that the topmost nanostructure 106B in the NFET 100N is formed to have the thickness T5 greater than the thickness T2 for increasing on-current of the NFET 100N, thereby improving the performance of the CFET 100A.

Similarly, in FIG. 4, the middle portion 106m of the bottommost nanostructure 106A in the PFET 100P in the CFET 100B have the thickness T6 greater than the thickness T1 of the middle portion 106m of the other nanostructure 106A in the PFET 100P. In the present embodiments, the side portions 106s of the bottommost nanostructure 106B in the PFET 100P also have the thickness T3. The thickness T6 of the middle portions 106m of the bottommost nanostructure 106A in the PFET 100P is also greater than the thickness T2 of the middle portions 106m of the nanostructures 106B in the NFET 100N. In some embodiments, a difference between the thickness T6 of the middle portion 106m of the bottommost nanostructure 106A in the PFET 100P and the thickness T1 of the middle portion 106m of the other nanostructure 106A in the PFET 100P (i.e., T6−T1) is in a range from about 0.5 nm to about 3 nm. Such structure is due to that the bottommost nanostructure 106A in the PFET 100P in the CFET 100B is closest to the source/drain contact 130-3 under and in contact with the source/drain features 118P, so that the bottommost nanostructure 106A in the PFET 100P is formed to have the thickness T6 greater than the thickness T1 for increasing on-current of the PFET 100P, thereby improving the performance of the CFET 100B. It should be noted that the bottommost nanostructure and the topmost nanostructure may be both formed to have larger middle portion thickness in the case of the source/drain contacts connected to source/drain features of NFET and the source/drain contacts connected to source/drain features of PFET are formed in the same CFET.

FIGS. 5 and 6 are X-Z cross-sectional views of the semiconductor device 100, in accordance with some alternative embodiments of the present disclosure. The semiconductor devices 100 shown in FIGS. 5 and 6 are similar to the semiconductor device 100 shown in FIGS. 3 and 4, respectively. In FIG. 5, the side portions 106p of the topmost nanostructure 106B in the NFET 100N in the CFET 100A have the thickness T7 greater than the thickness T4 of the side portions 106s of the other nanostructure 106B in the NFET 100N. The thickness T3 of the side portions 106p of the nanostructures 106A in the PFET 100P is greater than the thickness T7 of the side portions 106p of the topmost nanostructure 106B in the NFET 100N. In some embodiments, a difference between the thickness T7 of the side portions 106p of the topmost nanostructure 106B in the NFET 100N and the thickness T4 of the side portions 106p of the other nanostructure 106B in the NFET 100N (i.e., T7−T4) is in a range from about 0.5 nm to about 5 nm. Such structure is due to that the topmost nanostructure 106B in the NFET 100N in the CFET 100A is closest to the source/drain contacts 130-1 and 130-2, so that the topmost nanostructure 106B in the NFET 100N is formed to have the thickness T7 greater than the thickness T4 for increasing on-current of the NFET 100N, thereby improving the performance of the CFET 100A.

Similarly, in FIG. 6, the side portions 106p of the bottommost nanostructure 106A in the PFET 100P in the CFET 100B have the thickness T8 greater than the thickness T3 of the side portions 106p of the other nanostructure 106A in the PFET 100P. The thickness T8 of the side portions 106p of the bottommost nanostructure 106A in the PFET 100P is also greater than the thickness T4 of the side portions 106p of the nanostructures 106B in the NFET 100N. In some embodiments, a difference between the thickness T8 of the side portions 106p of the bottommost nanostructure 106A in the PFET 100P and the thickness T3 of the side portions 106p of the other nanostructure 106A in the PFET 100P (i.e., T8−T3) is in a range from about 0.5 nm to about 5 nm. Such structure is due to that the bottommost nanostructure 106A in the PFET 100P in the CFET 100B is closest to the source/drain contact 130-3, so that the bottommost nanostructure 106A in the PFET 100P is formed to have the thickness T8 greater than the thickness T3 for increasing on-current of the PFET 100P, thereby improving the performance of the CFET 100B. It should be noted that the bottommost nanostructure and the topmost nanostructure may be both formed to have larger side portion thickness in the case of the source/drain contacts connected to source/drain features of NFET and the source/drain contacts connected to source/drain features of PFET are formed in the same CFET.

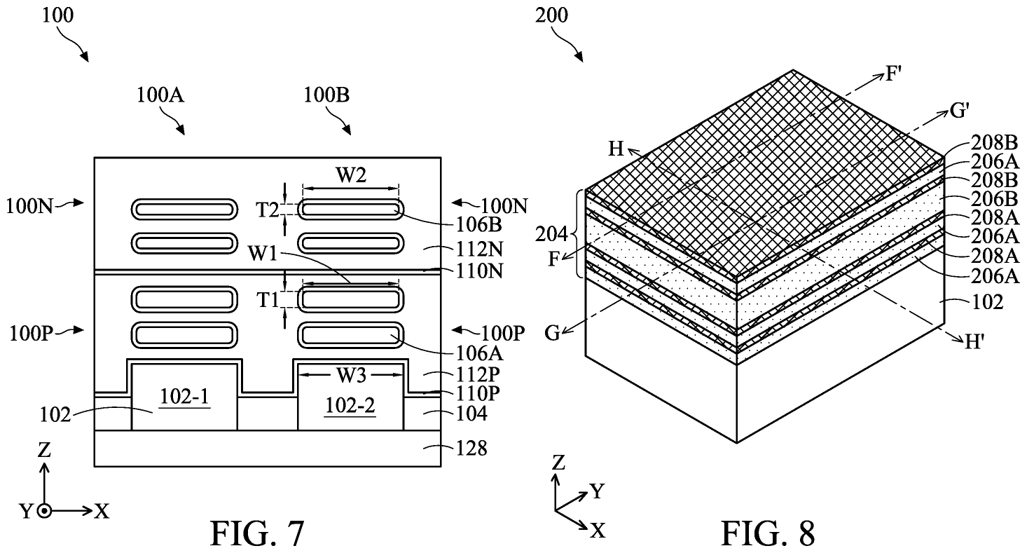

FIG. 7 is a Y-Z cross-sectional view of the semiconductor device 300, in accordance with some alternative embodiments of the present disclosure. The semiconductor device 100 shown in FIG. 7 is similar to the semiconductor device 100 shown in FIG. 1C. Referring back to FIG. 1C, as discussed above, the width W1 of the middle portions 106m of the nanostructures 106A in the PFETs 100P in the Y-direction is greater than the width W2 of the middle portions 106m of the nanostructures 106B in the NFETs 100N in the Y-direction, and the width W1 of the middle portions 106m of the nanostructures 106A in the PFETs 100P in the Y-direction is the same as the width of the substrate 102 (more specifically, the width of the base portions 102-1 and 102-2) in the Y-direction, in accordance with some embodiments. In FIG. 7, the width W3 of the substrate 102 (more specifically, the width of the base portions 102-1 and 102-2) in the Y-direction is greater than the width W1 of the middle portions 106m of the nanostructures 106A in the PFETs 100P in the Y-direction, in accordance with some embodiments. In some embodiments, a difference between the width W3 of the substrate 102 (more specifically, the width of the base portions 102-1 and 102-2) in the Y-direction and the width W1 of the middle portions 106m of the nanostructures 106A in the PFETs 100P in the Y-direction (i.e., W3−W1) is in a range from about 1 nm to about 10 nm. Therefore, with such wider width W3 of the substrate 102 (more specifically, the width of the base portions 102-1 and 102-2), the active area bending (or oxide diffusion (OD) bending) may be prevented.

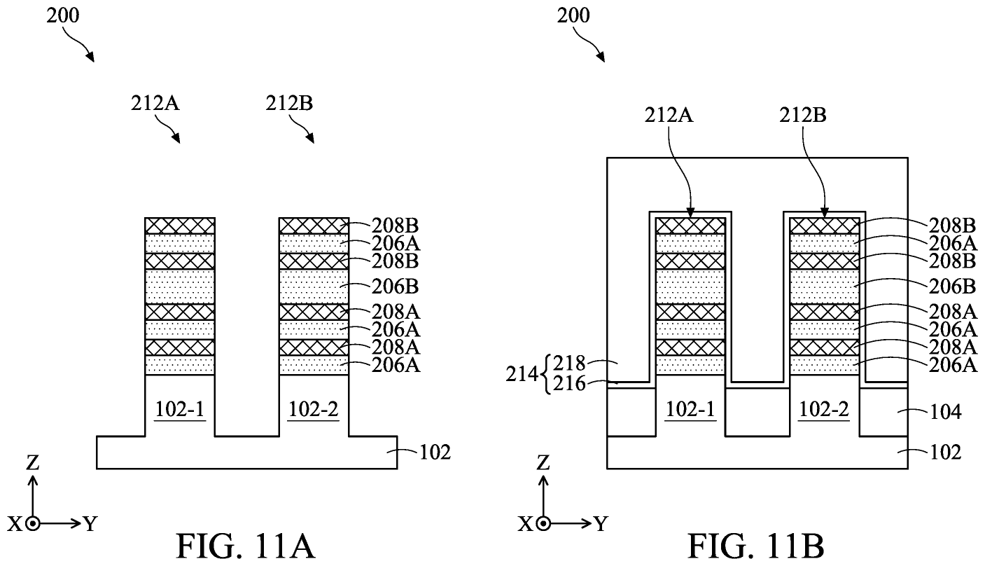

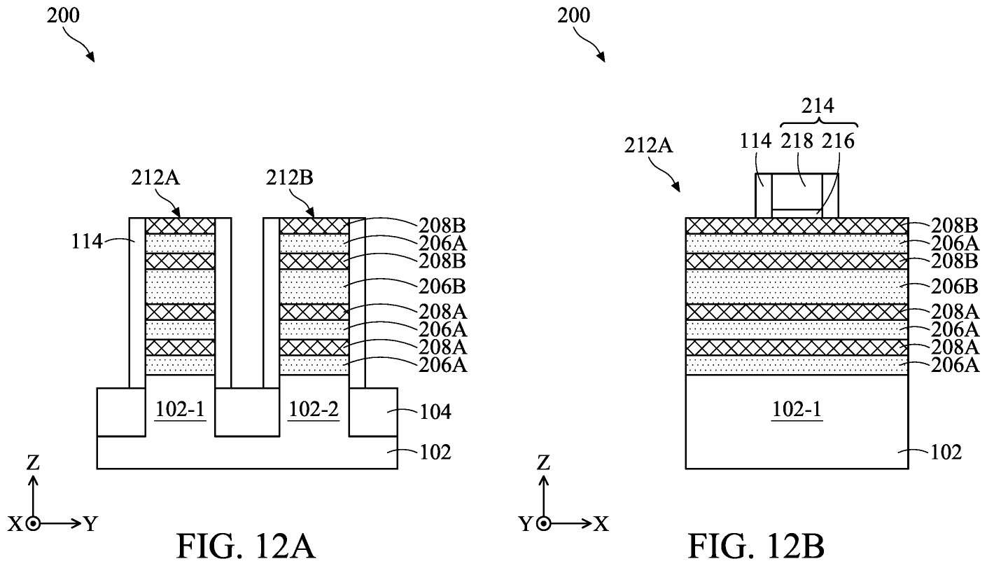

The formation of the semiconductor device 100 are described in detail in below. The formation of the semiconductor device 100 starts from a workpiece 200. FIG. 8 is a perspective view of a workpiece 200 at a fabrication stage, in accordance with some embodiments of the present disclosure. FIGS. 9, 10, 11B, 21B, 22B, 23B, and 24B are Y-Z cross-sectional views of the workpiece 200 at various fabrication stages along a line F-F′ of FIG. 8, in accordance with some embodiments of the present disclosure. FIGS. 11A, 12A, 13A, 14A, 15A, 16A, 17A, 18A, 19A, and 20A are Y-Z cross-sectional views of the workpiece at various fabrication stages along a line G-G′ of FIG. 8, in accordance with some embodiments of the present disclosure. FIGS. 12B, 13B, 14B, 15B, 16B, 117B, 18B, 19B, 20B, 21A, 22A, 23A, and 28A are Y-Z cross-sectional views of the workpiece at various fabrication stages along a line H-H′ of FIG. 8, in accordance with some embodiments of the present disclosure.

Referring to FIG. 8, the workpiece 200 is provided. The workpiece 200 includes a substrate 102 and a stack 204 over the substrate 102. In some embodiments, the substrate 102 contains a semiconductor material, such as bulk silicon (Si). In some other embodiments, the substrate 102 may include other semiconductors such as germanium (Ge), silicon germanium (SiGe), or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 102 may also include an insulating layer, such as a silicon oxide layer, to have a silicon-on-insulator (SOI) structure or a germanium-on-insulator (GOI) structure. In some embodiments, the substrate 102 may include one or more well regions, such as n-type well regions doped with an n-type dopant (i.e., phosphorus (P) or arsenic (As)) or p-type well regions doped with a p-type dopant (i.e., boron (B)), for forming different types of devices. The doping the n-type wells and the p-type wells may be formed using ion implantation or thermal diffusion.

The stack 204 includes semiconductor layers 206 (including semiconductor layers 206A and a semiconductor layer 206B) and 208 (including semiconductor layers 208A and 208B), and the semiconductor layers 206 and 208 are alternately stacked in the Z-direction. As shown in FIG. 8, a thickness of the semiconductor layer 206B is greater than a thickness of the semiconductor layers 206A. In some embodiments, the semiconductor layer 206B is form vertically between a group of the semiconductor layers 208A and a group of the semiconductor layers 208B.

In some embodiments, the thickness of the semiconductor layers 208A is greater than the semiconductor layers 208B for the semiconductor device 100 shown in FIG. 2. In other embodiments, the thickness of the semiconductor layers 208A and the thickness of the semiconductor layers 208B are the same for the semiconductor device 100 shown in FIGS. 1A to 1E. In yet some embodiments, the thickness of the topmost semiconductor layer 208B is greater than the thickness of the other semiconductor layer 208B for the semiconductor device 100 shown in FIG. 9. In some embodiments, the thickness of the bottommost semiconductor layer 208A is greater than the thickness of the other semiconductor layer 208A for the semiconductor device 100 shown in FIG. 10.

The semiconductor layers 206 and the semiconductor layers 208 may have different semiconductor compositions. In some embodiments, semiconductor layers 206 are formed of silicon germanium (SiGe) and the semiconductor layers 208 are formed of silicon (Si). In these embodiments, the additional germanium content in the semiconductor layers 206 allow selective removal or recess of the semiconductor layers 206 without substantial damages to the semiconductor layers 208, so that the semiconductor layers 206 are also referred to as sacrificial layers.

In some embodiments, the semiconductor layers 206 and 208 are epitaxially grown over (on) the substrate 102 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized. The semiconductor layers 206 and the semiconductor layers 208 are deposited alternatingly, one-after-another, to form the stack 204.

The two (2) semiconductor layers 208A are used for the PFETs 100P of the CFETs 100A and 100B and the two (2) semiconductor layers 208B are used for the NFETs 100N of the CFETs 100A and 100B. It should be noted that four (4) layers of the semiconductor layers 106 and four (4) layers of the semiconductor layers 108 are alternately and vertically arranged (or stacked) as shown in FIG. 8, which are for illustrative purposes only and not intended to be limiting beyond what is specifically recited in the claims. The number of the layers depends on the desired number of channels members for the semiconductor device.

Referring to FIG. 5, the substrate 102 and the stack 204 are then patterned to form fins 212A and 212B (may be collectively referred to as fins 212) over the substrate 102. For patterning purposes, the workpiece 200 may also include a hard mask layer 210 over the stack 204 before the patterning of the substrate 102 and the stack 204. The hard mask layer 210 may be a single layer or a multi-layer. In some embodiments, the hard mask layer 210 is a single layer and includes a silicon germanium layer. In some embodiments, the hard mask layer 210 is a multi-layer and includes a silicon nitride layer and a silicon oxide layer over the silicon nitride layer. In some other embodiments, the hard mask layer 210 is a multi-layer and includes a silicon germanium layer and a silicon layer over the silicon germanium layer.

As shown in FIG. 9, each of the fins 212 includes a base fin (i.e., the base portions 102-1 and 102-1 of the substrate 102 discussed above) formed from the substrate 102 and a stack portion formed from the stack 204 over the base portion. The fins 212A and 212B are arranged in the Y-direction.

The fins 212 may be patterned using suitable processes including double-patterning or multi-patterning processes. For example, in some embodiments, a material layer is formed over a substrate and patterned using a photolithography process. Spacers are formed alongside the patterned material layer using a self-aligned process. The material layer is then removed, and the remaining spacers, or mandrels, may then be used to pattern the fins 212 by etching the stack 204 and the substrate 102. The etching process may include dry etching, wet etching, reactive ion etching (RIE), and/or other suitable processes.

Referring to FIG. 10, isolation feature 104 is formed. After the fin 212 is formed, the isolation feature 104 are formed over the substrate 102. In some embodiments, the isolation structure 104 extends in the X-direction (not shown) and is arranged with the fins 212 in the Y-direction. In some other aspects, the isolation feature 104 is formed around the fins 212. The isolation feature 104 may also be referred to as shallow trench isolation (STI) feature. In some embodiments, a dielectric material for the isolation feature 104 is first deposited over the workpiece 200. In some embodiments, the dielectric material may include silicon oxide, silicon nitride, silicon oxynitride, fluorine-doped silicate glass (FSG), a low-k dielectric, combinations thereof, and/or other suitable materials. In various embodiments, the dielectric material may be deposited by a CVD, a subatmospheric CVD (SACVD), a flowable CVD (FCVD), an ALD, spin-on coating, and/or other suitable process. The deposited dielectric material is then thinned and planarized, for example by a chemical mechanical polishing (CMP) process. The planarized dielectric material is further recessed by a dry etching process, a wet etching process, and/or a combination thereof to form the isolation feature 104. As shown in FIG. 10, the stack portions of the fins 212 rise above the isolation feature 104 while the base portions 102-1 and 102-2 are surrounded by the isolation feature 104. In other words, the top surfaces of the substrate 102 is higher than top surfaces of the isolation feature 104. In some embodiments, before the formation of the isolation feature 104, liner layers are conformally deposited over the substrate 102 using ALD or CVD.

Referring to FIGS. 11A and 11B, the mask layer 210 is removed and a dummy gate structure 214 is formed over the fins 212 and over the isolation feature 104. The dummy gate structure 214 may be configured to extend along the Y-direction and wrap around top surfaces and side surfaces of the fins 212. In some embodiments, to form the dummy gate structure 214, a dummy interfacial material of a dummy interfacial layer 216 is first formed over fins 212 and over the isolation feature 104. In some embodiments, the dummy interfacial layer 216 may include, for example, a dielectric material such as a nitride (e.g., silicon nitride, silicon oxynitride), a carbide (e.g., silicon carbide), an oxide (e.g., silicon oxide), or some other suitable material. Then, in some embodiments, a dummy gate material of a dummy gate electrode 218 is formed over the dummy interfacial material. The dummy gate material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or combinations thereof The dummy gate material and/or the dummy interfacial material may be formed by way of a thermal oxidation process and/or a deposition process (e.g., PVD, CVD, PECVD, and ALD). After the formation of the dummy gate material and the dummy interfacial material, lithography and etching processes may be performed to remove portions of the dummy gate material and the dummy interfacial material, thereby forming the dummy gate structure 214 with dummy gate electrode 218 and the dummy interfacial layer 216. The dummy gate structure 214 may undergo a gate replacement process through subsequent processing to form metal gates, such as a high-k metal gate, as discussed in greater detail below.

Referring to FIGS. 12A and 12B, after the formation of the dummy gate structure 214, the gate spacers 114 are formed on sidewalls of the dummy gate structure 214, over the top surfaces of the fins 212, and on the sidewalls of the fins 212. More specifically, the gate spacers 114 are formed on opposite the sidewalls of the fins 212, as shown in FIG. 12A, and formed on opposite the sidewalls of the dummy gate structures 214, as shown in FIG. 12B. The gate spacers 114 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), carbon doped oxide, nitrogen doped oxide, porous oxide, or combinations thereof. The gate spacers 114 may include a single layer or a multi-layer structure. In some embodiments, the gate spacers 114 may be formed by conformally depositing a spacer layer (containing the dielectric material) over the isolation feature 104, the fins 212, and the dummy gate structure 214, followed by an anisotropic etching process to remove top portions of the spacer layer from the top surfaces of the isolation feature 104, the fins 212, and the dummy gate structure 214. After the etching process, portions of the spacer layer on the sidewall surfaces of the fins 212 and the dummy gate structure 214 substantially remain and become the gate spacers 114. In some embodiments, the anisotropic etching process is a dry (e.g., plasma) etching process. Additionally or alternatively, the formation of the gate spacers 114 may also involve chemical oxidation, thermal oxidation, ALD, CVD, and/or other suitable methods. The gate spacers 114 may also be interchangeably referred to as gate top spacers or top spacers.

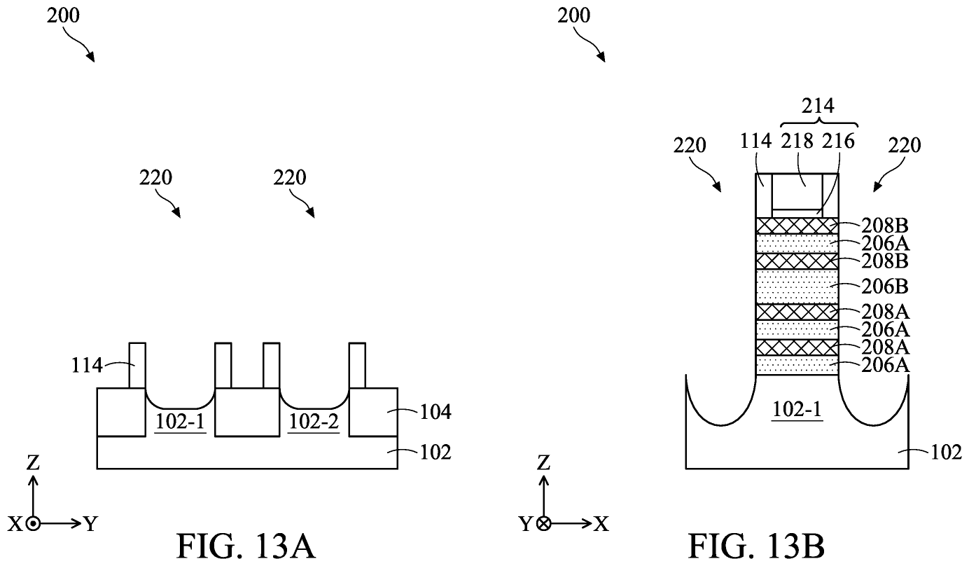

Referring to FIGS. 13A and 13B, the fins 212 are recessed to form source/drain trenches 220 in the fins 212 (or passing through the semiconductor layers 206 and 208). Specifically, the source/drain trenches 220 may be formed by performing one or more etching processes to remove portions of the semiconductor layers 206, the semiconductor layers 208, and the substrate 102 that do not vertically overlap or be covered by the dummy gate structure 214 and the gate spacers 114. In some embodiments, a single etchant may be used to remove the semiconductor layers 206, the semiconductor layers 208, and the substrate 102, whereas in other embodiments, multiple etchants may be used to perform the etching process. In some embodiments, portions of the gate spacers 114 on the opposite sidewalls of the fins 212 are removed, as shown in FIG. 13A. The thickness of the gate spacers 114 on the opposite sidewalls of the fins 212 are reduced.

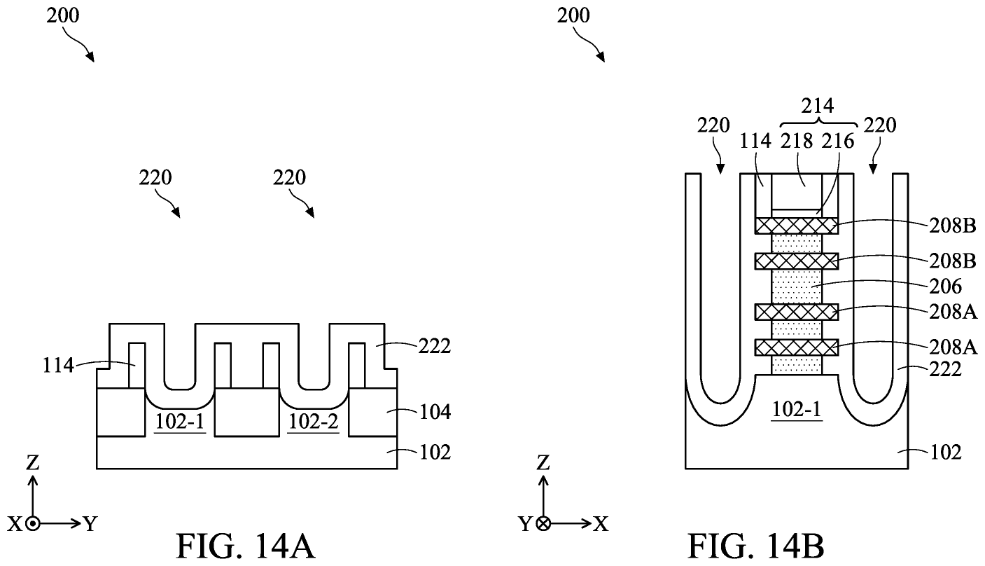

Referring to FIGS. 14A and 14B, side portions of the semiconductor layers 206 (including the semiconductor layers 206A and 206B) are removed via a selective etching process, and the semiconductor layer 208 is not removed. Specifically, the selective etching process is performed that selectively etches the side portions of the semiconductor layers 206 below the gate spacers 114 through the source/drain trenches 220, with minimal (or no) etching of the semiconductor layer 206 and the semiconductor layers 208, such that gaps are vertically formed between the semiconductor layers 208 as well as between the semiconductor layers 208 and the substrate 102, below the gate spacers 114. The etching process is configured to laterally etch (e.g., along the X-direction) the semiconductor layers 206 below the gate spacers 402. The selective etching process is a dry etching process, a wet etching process, other suitable etching process, or combinations thereof.

Still referring to FIGS. 14A and 14B, a spacer layer 222 is conformally formed into the source/drain trenches 220 and the gaps. More specifically, a deposition process is performed to form the spacer layer 222 into the source/drain trenches 220 and the gaps 602, such as CVD, PVD, ALD, HDPCVD, MOCVD, RPCVD, PECVD, LPCVD, ALCVD, APCVD, other suitable methods, or combinations thereof. The spacer layer 222 partially (and, in some embodiments, completely) fills the source/drain trenches 220 and fully fills the gaps, as shown in FIG. 14B. The deposition process is configured to ensure that the spacer layer 222 fills the gaps between the semiconductor layers 208 as well as between the semiconductor layer 208 and the substrate 102 under the gate spacers 114. Furthermore, the spacer layer 222 is also conformally formed on the gate spacers 114 and the isolation feature 104, as shown in FIG. 14A.

The spacer layer 222 includes a material that is different than a material of the semiconductor layers 208 and a material of the gate spacers 114 to achieve desired etching selectivity during the etching process. In some embodiments, the spacer layer 222 include a dielectric material that includes silicon, oxygen, carbon, nitrogen, other suitable material, or combinations thereof (for example, silicon oxide (SiO₂), silicon oxynitride (SiON), silicon oxycarbide (SiOC), silicon carbon nitride (SiCN), silicon oxycarbon nitride (SiOCN)). In some embodiments, the spacer layer 222 include a low-k dielectric material, such as those described herein.

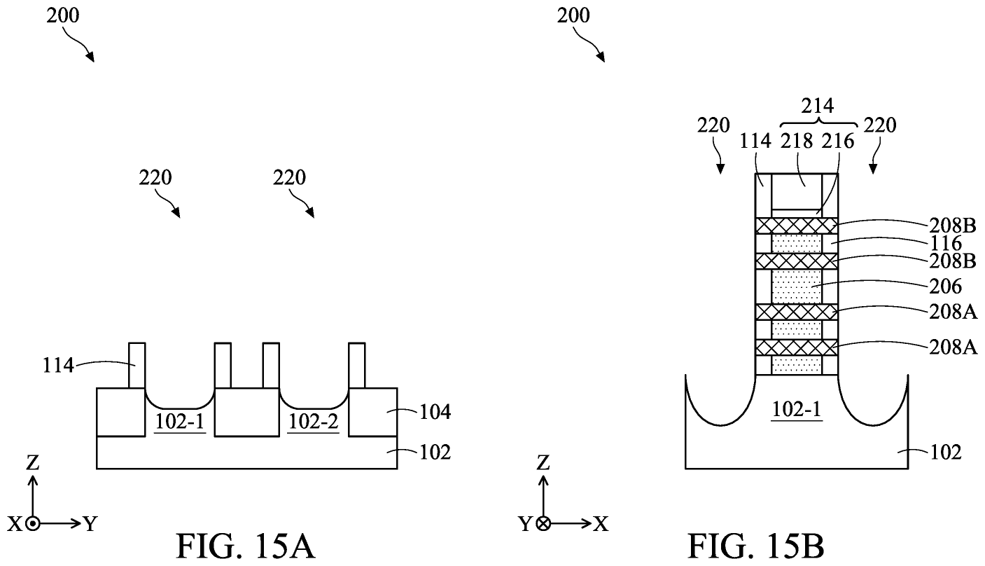

Referring to FIGS. 15A and 15B, the inner spacers 116 are formed to fill the gaps between the semiconductor layers 208 as well as between the semiconductor layer 208 and the substrate 102. More specifically, an etching process is then performed that selectively etches the spacer layer 222 to form the inner spacers 116 with minimal (to no) etching of the semiconductor layer 208, the substrate 102, the dummy gate structures 302, and the gate spacers 114. The etching process may be an anisotropic etching process, such that the spacer layer 222 that do not vertically overlap or be covered by the dummy gate structure 214 and the gate spacers 114 are removed. The spacer layer 222 on the gate spacers 114 and the isolation feature 104 are removed, as shown in FIG. 15A. In some embodiments, sidewalls of the inner spacers 116 are aligned to the sidewalls of the gate spacers 114 and the semiconductor layers 208, as shown in FIG. 15B. Therefore, the inner spacers 116 are formed on opposite sides of the dummy gate structure 214. Furthermore, the inner spacers 116 are also vertically between the semiconductor layers 208 as well as between the semiconductor layer 208 and the substrate 102, in accordance with some embodiments.

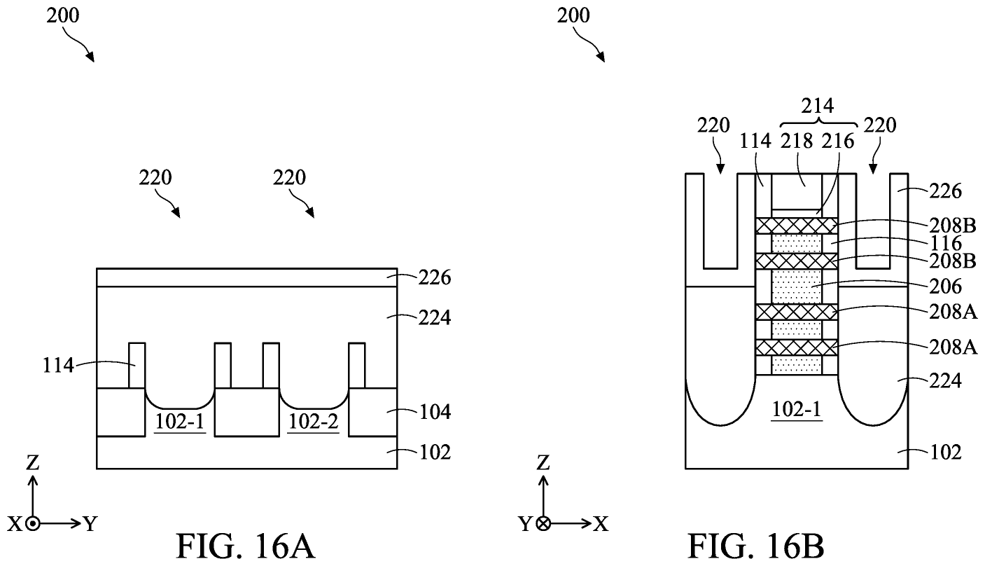

Referring to FIGS. 16A and 16B, polymer layers 224 and dielectric layers 226 are formed in the source/drain trenches 220. More specifically, the polymer layers 224 are first formed in lower parts of the source/drain trenches 220 to cover the top surfaces of the substrate 102 and the sidewalls of the semiconductor layers 208A (which are used for the PFET of the CFET, such as the PFETs 100P of the CFETs 100A and 100B discussed above) and the inner spacers 116 (which are between the semiconductor layers 208A) exposed in the source/drain trenches 220. In some embodiments, top surfaces of the polymer layers 224 are lower than the semiconductor layers 208B. Furthermore, the polymer layers 224 is also formed on the gate spacers 114 and the isolation feature 104, as shown in FIG. 16A.

After the formation of the polymer layers 224, the dielectric layers 226 are conformally formed over the polymer layers 224 and on the sidewalls of the semiconductor layers 208B (which are used for the NFET of the CFET, such as the NFETs 100N of the CFETs 100A and 100B discussed above), the gate spacers 114, and the inner spacers 116 (which are between the semiconductor layers 208B). The polymer layers 224 are formed of fluorine-containing polymer and its molecular structure includes silicon (Si), carbon (C), nitrogen (N), or fluorine (F). In one example, the polymer layers 1002 include fluorinated silicone or fluorinated polysilane. In some embodiments, the polymer layers 224 are spin-on-carbon layers. The polymer layers 224 may be deposited using CVD, flowable CVD (FCVD), or spin-on coating. The dielectric layers 226 may include aluminum oxide (Al₂O₃).

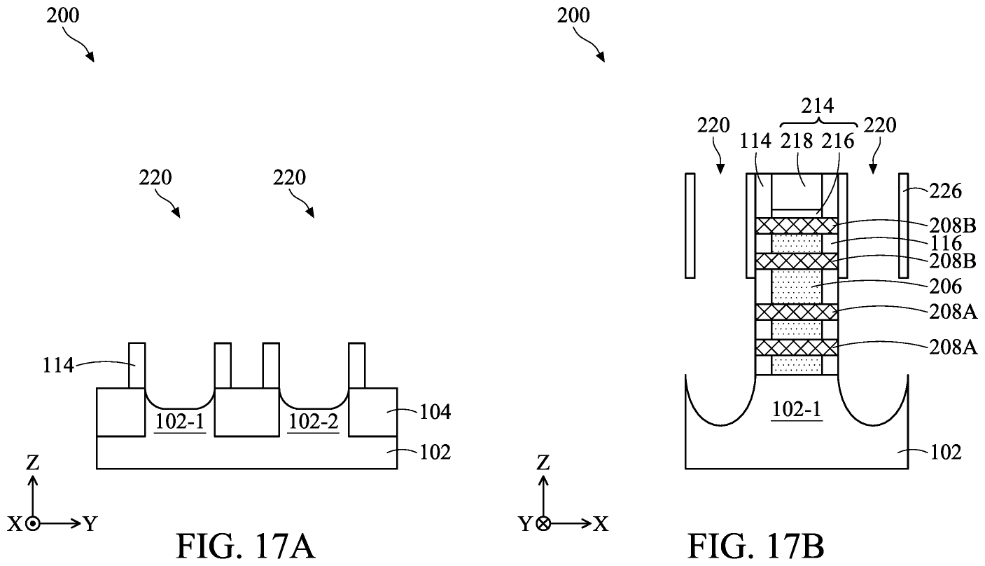

Referring to FIGS. 17A and 17B, horizontal portions of the dielectric layers 226 and the polymer layers 224 are removed. More specifically, an anisotropic etching process is performed to remove the horizontal portions of the dielectric layers 226 to exposed top surfaces of the polymer layers 224, and then a selective etching process is performed to remove the polymer layers 224. In some embodiments, portions of vertical portions of the dielectric layers 226 are removed or trimmed, but the vertical portions of the dielectric layers 226 still cover the sidewalls of the gate spacers 114 and the semiconductor layers 208B, as shown in FIG. 17B. The selective etching process is performed that selectively etches the polymer layers 224 below the dielectric layers 226 through the source/drain trenches 220, with minimal (or no) etching of the semiconductor layers 208A, the substrate 102, and the inner spacers 116. The selective etching process is a dry etching process, a wet etching process, other suitable etching process, or combinations thereof.

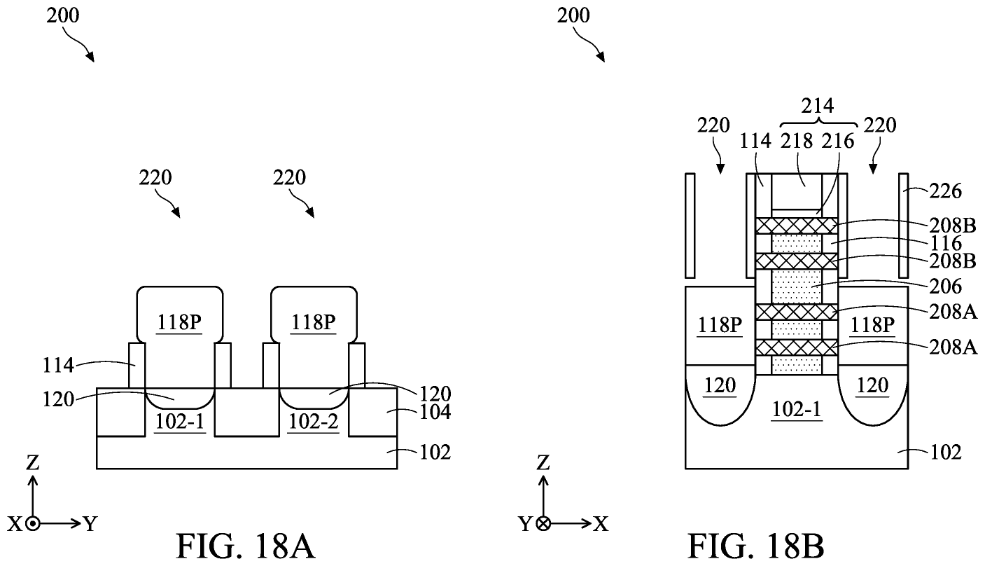

Referring to FIGS. 18A and 18B, after the removal of the polymer layers 1002, the bottom dielectric layers 120 and the source/drain features 118P are formed in the lower parts of the source/drain trenches 220 and below the dielectric layers 226. More specifically, the bottom dielectric layers 120 are formed over the substrate 102 exposed in the source/drain trenches 220, and the source/drain features 118P are formed over the bottom dielectric layers 120. As such, the bottom dielectric layers 120 are vertically between and in contact with the source/drain features 118P and the substrate 102 in the Z-direction. The top surfaces of the bottom dielectric layers 120 are higher than the topmost surfaces of the substrate 102 (i.e., the top surfaces of the base portions 102-1 and 102-2) to ensure that the bottom dielectric layers 120 separate the source/drain features 118P from the substrate 102.

The source/drain features 118P are also formed on opposite sides of the dummy gate structure 214 in the X-direction, as shown in FIG. 18B. The source/drain features 118P are connected to and in contact with the semiconductor layers 208A. In some aspects, the semiconductor layers 208A connect one source/drain feature 118P to another source/drain feature 118P. In some embodiments, the source/drain features 118P may have top surfaces that extend higher than top surfaces of the topmost semiconductor layers 208A (e.g., in the Z-direction). In other embodiments, the top surfaces of the source/drain features 118P substantially level with the top surfaces of the topmost semiconductor layers 208A. Furthermore, the top surfaces of the source/drain features 118P are lower than the bottom surfaces of the dielectric layers 226 and the semiconductor layers 208B.

One or more epitaxy processes may be employed to grow the source/drain features 118P. Epitaxy processes can implement CVD deposition techniques (for example, vapor-phase epitaxy (VPE), UHVCVD, LPCVD, and/or PECVD), molecular beam epitaxy, other suitable SEG processes, or combinations thereof. The source/drain features 118P are grown from the semiconductor layers 208A rather than the substrate 102 and the semiconductor layers 208B due to the bottom dielectric layers 120 cover the top surfaces of the substrate 102 and the dielectric layers 226 cover the sidewalls of the semiconductor layers 208B. The source/drain features 118P may include any suitable semiconductor materials. For example, the source/drain features 118P used for the PFETs of the CFETs (e.g., the PFETs 100P of the CFETs 100A and 100B shown in FIGS. 1A to 1E) may include epitaxially-grown material selected from a group consisting of boron-doped SiGe, boron-doped SiGeC, boron-doped Ge, boron-doped Si, boron and carbon doped SiGe, or a combination thereof. The source/drain features 1102P may also be referred to as source/drain, or source/drain regions. In some embodiments, source/drain feature(s) 118P may refer to a source or a drain, individually or collectively dependent upon the context. In some embodiments, the source/drain features 118P may be referred to as P-type source/drain features. The source/drain features 118P may be doped in-situ or ex-situ. One or more annealing processes may be performed to activate the dopants in the source/drain features 118P. The annealing processes may include rapid thermal annealing (RTA) and/or laser annealing processes.

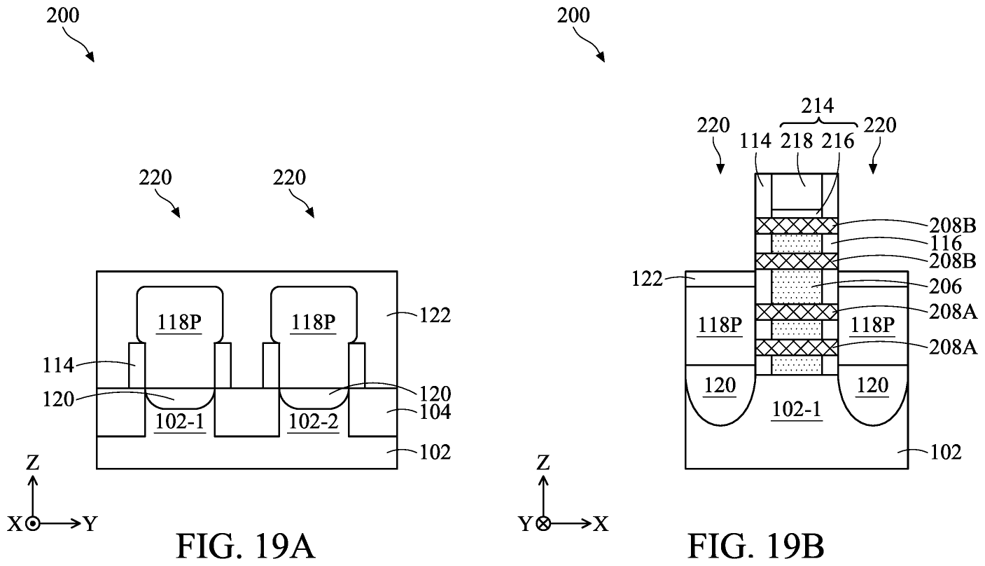

Referring to FIGS. 19A and 19B, the dielectric layers 226 are removed via a selective etching process, and then the interlayer dielectric (ILD) layer 122 over the substrate 102, the isolation feature 104, and the source/drain features 118P are formed in the source/drain trenches 220. Specifically, the selective etching process is performed that selectively etches the dielectric layers 226 over the source/drain features 118P through the source/drain trenches 220, with minimal (or no) etching of the semiconductor layers 208B, the gate spacers 114, and the inner spacers 116. The selective etching process is a dry etching process, a wet etching process, other suitable etching process, or combinations thereof.

After the removal of the dielectric layers 226, the ILD layer 122 is then formed over the substrate 102, the isolation feature 104, and the source/drain features 118P and between the spaces between the source/drain features 118P. Then, the ILD layer 122 over the source/drain features 118P are recessed by performing one or more lithography and etching processes, so that the sidewalls of the semiconductor layers 208B over the source/drain features 118P are exposed.

The ILD layer 122 may comprise tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD layer 122 may be formed by PECVD (plasma enhanced CVD), FCVD (flowable CVD), or other suitable methods.

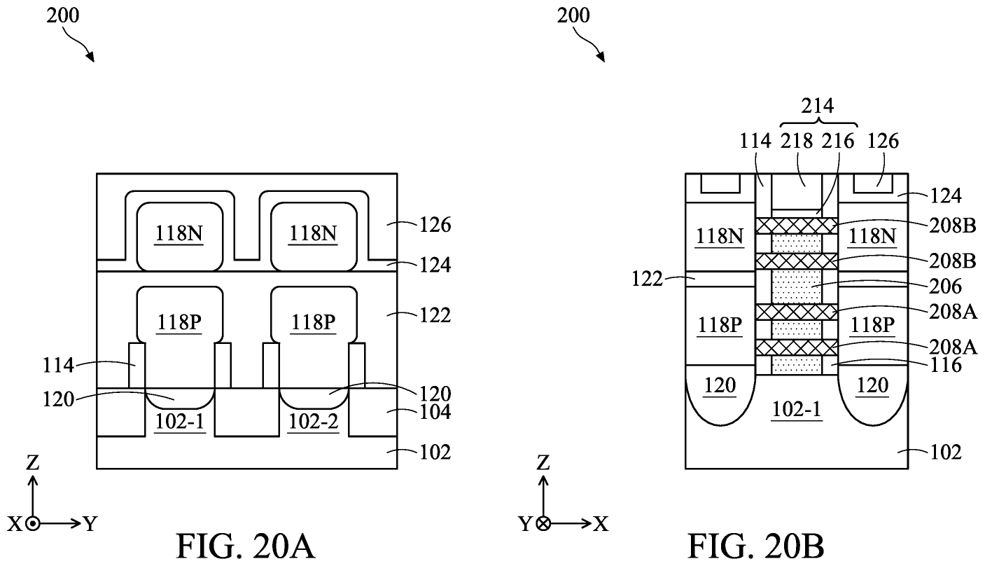

Referring to FIGS. 20A and 20B, the source/drain features 118N are formed in the source/drain trenches 220. Specifically, the source/drain features 118N are formed over the ILD layer 1004 in the source/drain trenches 220. The source/drain features 118N are also formed on opposite sides of the dummy gate structure 214 in the X-direction. The source/drain features 118N are connected to and in contact with the semiconductor layers 208B. In some aspects, the semiconductor layers 208B connect one source/drain feature 118N to another source/drain feature 118N. In some embodiments, the source/drain features 118N may have top surfaces that extend higher than top surfaces of the topmost semiconductor layers 208B (e.g., in the Z-direction). In other embodiments, the top surfaces of the source/drain features 118N are substantially level with the top surfaces of the topmost semiconductor layers 106B. In some embodiments, the bottom surfaces of the source/drain features 118N are lower than bottom surfaces of the bottommost semiconductor layers 208B. In other embodiments, the bottom surfaces of the source/drain features 118N are substantially level with the bottom surfaces of the bottommost semiconductor layers 208B.

One or more epitaxy processes may be employed to grow the source/drain features 118N. Epitaxy processes can implement CVD deposition techniques (for example, vapor-phase epitaxy (VPE), UHVCVD, LPCVD, and/or PECVD), molecular beam epitaxy, other suitable SEG processes, or combinations thereof. The source/drain features 118N are grown from the semiconductor layers 208B. The source/drain features 118N may include any suitable semiconductor materials. For example, the source/drain features 118N used for the NFETs of the CFETs (e.g., the NFETs 100N of the CFETs 100A and 100B shown in FIGS. 1A to 1E) may include epitaxially-grown material selected from a group consisting of SiP, SiC, SiPC, SiAs, Si, or a combination thereof. The source/drain features 118N may also be referred to as source/drain, or source/drain regions. In some embodiments, source/drain feature(s) 118N may refer to a source or a drain, individually or collectively dependent upon the context. In some embodiments, the source/drain features 118N may be referred to as N-type source/drain features. The source/drain features 118N may be doped in-situ or ex-situ. One or more annealing processes may be performed to activate the dopants in the source/drain features 118N. The annealing processes may include rapid thermal annealing (RTA) and/or laser annealing processes.

Still referring to FIGS. 20A and 20B, contact etch stop layers (CESLs) 124 over the source/drain features 118N and the ILD layer 122 and an interlayer dielectric (ILD) layer 126 over the CESLs 124 are formed to fill the space between the source/drain features 118N. Specifically, the CESLs 124 are conformally formed on the sidewalls of the gate spacers 114. In some embodiments, the CESLs 124 are also conformally formed on the top surfaces and the sidewalls of the source/drain features 118N, as shown in FIG. 20A. The ILD layer 126 is formed over and between the CESLs 124 to fill the space in the CESLs 124 and between the gate spacers 114 and in the source/drain trenches 220. After the formation of the CESLs 124 and the ILD layer 126, a CMP process is performed to reduce heights of the CESLs 124 and the ILD layer 126 until top surfaces of the dummy gate electrode 218 of the dummy gate structure 214 are exposed.

The CESLs 124 include a material that is different than ILD layer 126. The CESLs 124 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AION, TaCN, ZrSi, or other suitable material(s); and may be formed by CVD, PVD, ALD, or other suitable methods. The ILD layer 126 may comprise tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD layer 1204 may be formed by PECVD (plasma enhanced CVD), FCVD (flowable CVD), or other suitable methods.

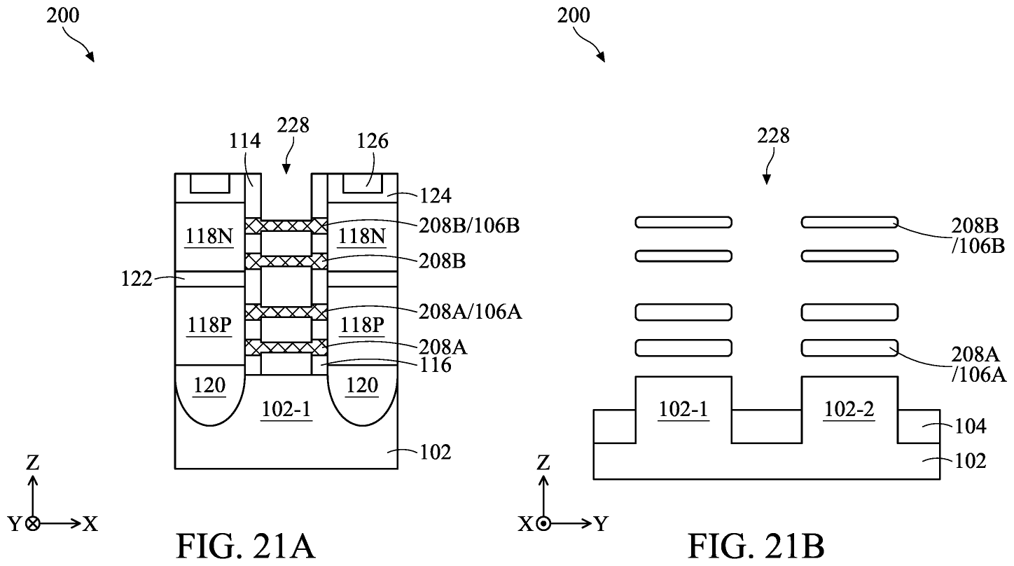

Referring to FIGS. 21A and 21B, the dummy gate structure 214 are selectively removed through any suitable lithography and etching processes. In some embodiments, the lithography process may include forming a photoresist layer (resist), exposing the resist to a pattern, performing a post-exposure bake process, and developing the resist to form a masking element, which exposes a region including the dummy gate structure 214. Then, the dummy gate structure 214 are selectively etched through the masking element. The gate spacers 114 may be used as the masking element or a part thereof. Etch selectivity may be achieved by selecting the appropriate etching chemicals, and the dummy gate structure 214 may be removed without substantially affecting the CESLs 124 and the ILD layer 126. The removal of the dummy gate structure 214 creates a gate trench 228. The gate trench 228 exposes the top surfaces of the topmost semiconductor layers 208A that underlies the dummy gate structure 214.

Still referring to FIGS. 21A and 21B, the semiconductor layers 206 of the fins 212 are selectively removed through the gate trench 228, using a wet or dry etching process for example, so that the semiconductor layers 208A and 208B are exposed in the gate trench 228 to form nanostructures 106A and 106B stacked over each other. As such, the semiconductor layers 208 may be referred to as nanostructures. Specifically, the semiconductor layers 208A (the nanostructures 106A) are stacked vertically in the Z-direction, and the semiconductor layers 208B (the nanostructures 106B) are directly over the semiconductor layers 208A and are stacked vertically in the Z-direction. Such a process may also be referred to as a wire release process, a nanowire release process, a nanosheet release process, a nanowire formation process, a nanosheet formation process, or a wire formation process.

In some embodiments, the removal of the semiconductor layers 206 causes the exposed semiconductor layers 208A or 208B to be spaced apart from each other in the vertical direction (e.g., in the Z-direction). The exposed semiconductor layers 208 extend longitudinally in the horizontal direction (e.g., in the X-direction). Furthermore, each of the semiconductor layers 208A connects one source/drain feature 118P to another source/drain feature 118P, and each of the semiconductor layers 208B connects one source/drain feature 118N to another source/drain feature 118N. In some embodiments, during the removal of the semiconductor layers 206, middle portions of the semiconductor layers 208A and 208B are partially removed to form the nanostructures 106A and 106B with the dumbbell-shapes in the X-Z cross-sectional view discussed above, as shown in FIGS. 1A and 21A.

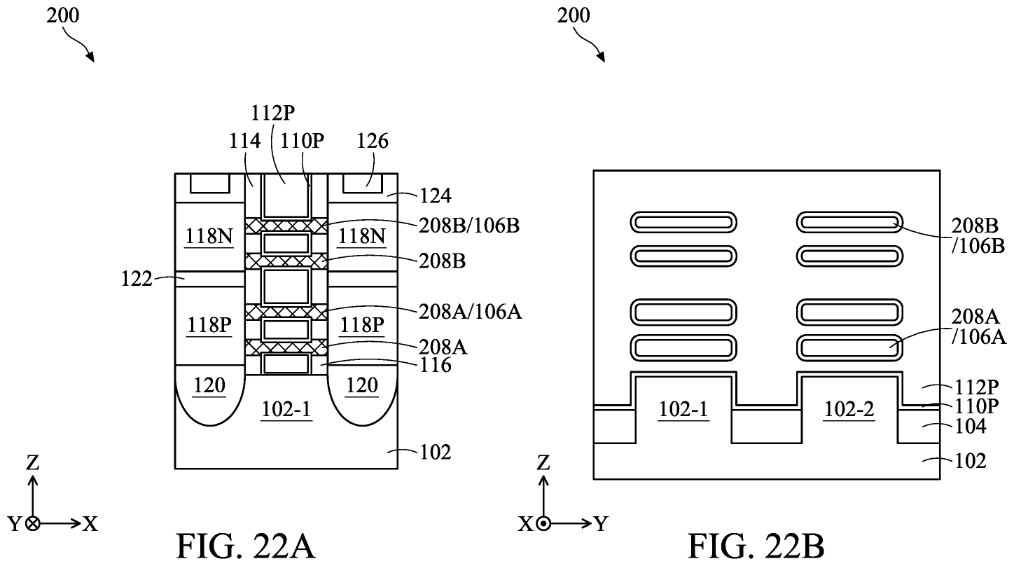

Referring to FIGS. 22A and 22B, the gate dielectric layer 110P and the gate electrode layer 112P are formed in the gate trench 228 to wrap around the semiconductor layers 208A and 208B (the nanostructures 106A and 106B). More specifically, the gate dielectric layer 110P wrap around each of the semiconductor layers 208A and 208B (the nanostructures 106A and 106B), and the gate electrode layer 112P wrap around the gate dielectric layer 110P and each of the semiconductor layers 208A and 208B (the nanostructures 106A and 106B). Additionally, the gate dielectric layer 110P is also formed on the sidewalls of the inner spacers 116 and the gate spacers 114 (shown in FIG. 22A), as well as over the top surfaces of the substrate 102 and the isolation feature 104 (shown in FIG. 22B).

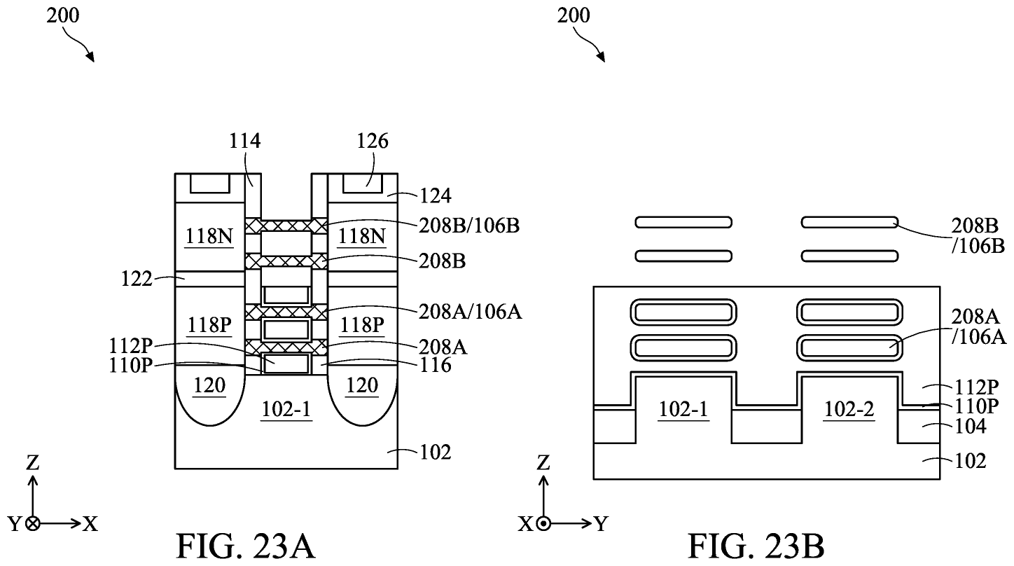

Referring to FIGS. 23A and 23B, the gate dielectric layer 110P and the gate electrode layer 112P in the gate trench 228 are etched back to expose (the middle portions 106m of) the semiconductor layers 208B (the nanostructures 106B). More specifically, portions of the gate dielectric layer 110P and the gate electrode layer 112P wrapping around the semiconductor layers 208B (the nanostructures 106B) are removed by performing one or more etching processes. The etching processes may be selective etching processes that selectively etch the gate dielectric layer 110P and the gate electrode layer 112P, with minimal (or no) etching of the semiconductor layers 208B (the nanostructures 106B), the gate spacers 114, and the inner spacers 116. The selective etching process is a dry etching process, a wet etching process, other suitable etching process, or combinations thereof. As shown in FIGS. 23A, after the etching processes, a top surface of the gate electrode layer 112P is lower than bottommost surfaces of the semiconductor layers 208B (the nanostructures 106B) and top surfaces of the ILD layer 122, in accordance with some embodiments.

As discussed in FIG. 8, in some embodiments, the thickness of the semiconductor layers 208A is greater than the semiconductor layers 208B for the semiconductor device 100 shown in FIG. 2. In such case, due to the semiconductor layers 208A and 208B undergo subsequent processes together (some portions may be partially removed), the thickness of (the middle portions 106m of) the semiconductor layers 208A (the nanostructures 106A) is still greater than the thickness of (the middle portions 106m of) the semiconductor layers 208B (the nanostructures 106B).

However, in some embodiments, an optional trimming process may be performed to trim the thickness of (the middle portions 106m of) the semiconductor layers 208B (the nanostructures 106B) after the gate dielectric layer 110P and the gate electrode layer 112P in the gate trench 228 are etched back shown in FIGS. 23A and 23B. The trimming process may be a selective etching process that selectively etch (the middle portions 106m of) the semiconductor layers 208B (the nanostructures 106B) exposed in the gate trench 228, with minimal (or no) etching of the gate dielectric layer 110P, the gate spacers 114, and the inner spacers 116. The selective etching process is a dry etching process, a wet etching process, other suitable etching process, or combinations thereof. Therefore, after the trimming process, the thickness of (the middle portions 106m of) the semiconductor layers 208B (the nanostructures 106B) exposed in the gate trench 228 is reduced.

In other embodiments, as discussed in FIG. 8, the thickness of the semiconductor layers 208A and the thickness of the semiconductor layers 208B are the same for the semiconductor device 100 shown in FIGS. 1A to 1E. As such, after the gate dielectric layer 110P and the gate electrode layer 112P in the gate trench 228 are etched back shown in FIGS. 23A and 23B, an additional trimming process as the optional trimming process discussed above may be performed to trim the thickness of (the middle portions 106m of) the semiconductor layers 208B (the nanostructures 106B). Therefore, after the trimming process, the thickness of (the middle portions 106m of) the semiconductor layers 208B (the nanostructures 106B) exposed in the gate trench 228 is reduced, such that the thickness of (the middle portions 106m of) the semiconductor layers 208A (the nanostructures 106A) is greater than the thickness of (the middle portions 106m of) the semiconductor layers 208B (the nanostructures 106B).

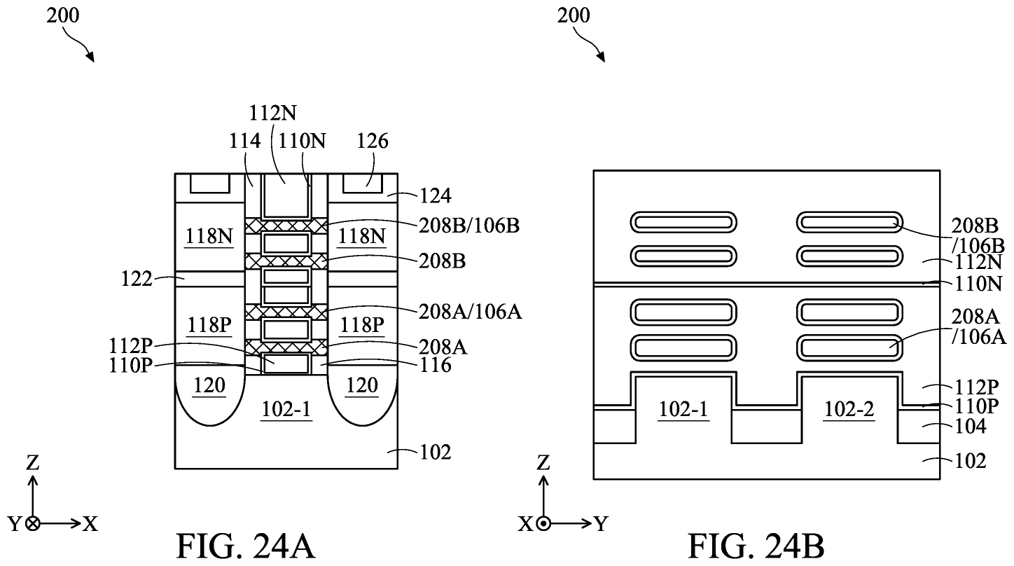

Referring to FIGS. 24A and 24B, the gate dielectric layer 110N and the gate electrode layer 112N are formed in the gate trench 228 and over the gate dielectric layer 110P and the gate electrode layer 112P to wrap around the semiconductor layers 208B (the nanostructures 106B). More specifically, the gate dielectric layer 110N wrap around each of the semiconductor layers 208B (the nanostructures 106B), and the gate electrode layer 112N wrap around the gate dielectric layer 110N and each of the semiconductor layers 208B (the nanostructures 106B). Additionally, the gate dielectric layer 110N is also formed on the sidewalls of the inner spacers 116 and the gate spacers 114 (shown in FIG. 24A), as well as over the top surface of the gate electrode layer 112P (shown in FIG. 22B). Furthermore, the gate dielectric layer 110N is further in contact with the gate dielectric layer 110P, as shown in FIG. 24A.

Therefore, the gate dielectric layer 110P, the gate electrode layer 112P, the gate dielectric layer 110N, and the gate electrode layer 112N may be together referred to as the gate structure 108 to replace the dummy gate structure 214. The gate dielectric layers 110P and 110N may include oxide with nitrogen doped dielectric material (initial layer) combined with metal content high-K dielectric material (K value (dielectric constant)>13). For example, the gate dielectric layers 110P and 110N may include hafnium oxide (HfO₂), which has a dielectric constant in a range from about 18 to about 40. Alternatively, the gate dielectric layers 110P and 110N may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr) TiO₃ (BST), Al₂O₃, Si₃N₄, oxynitrides (SiON), combinations thereof, or other suitable material. The gate dielectric layers 110P and 110N may be formed by chemical oxidation, thermal oxidation, ALD, CVD, and/or other suitable methods.

In some embodiments, the gate electrode layer 112P may include one or more P-type work function metal layers for PFETs 100P and the gate electrode layer 112N may include one or more N-type work function metal layers for NFETs 100N. In some embodiments, each of the gate electrode layers 112P and 112N may include a single layer or alternatively a multi-layer structure. Therefore, the gate dielectric layers 110P and 110N may be referred to as work function metal layers. The material of the N-type work function metal layers and the P-type work function metal may layers be the same. In some embodiments, the material of the N-type work function metal layers and the P-type work function metal layers are different.

In some embodiments, the N-type work function metal layers include a material such as Ti, Al, Ag, Mn, Zr, TiAl, TiAlC, TaC, TaCN, TaSiN, TaAl, TaAlC, TiAlN, other suitable N-type work function materials, or combinations thereof. For example, the N-type work function metal layer may be deposited utilizing ALD, CVD, or the like. However, any suitable materials and processes may be utilized to form the N-type work function metal layer 314N.

In some embodiments, the P-type work function metal layers include a material such as TiN, TaN, Ru, Mo, Al, WN, ZrSi₂, MoSi₂, TaSi₂, NiSi₂, other metal oxides, metal nitrides, metal silicates, transition metal-oxides, transition metal-nitrides, transition metal-silicates, oxynitrides of metals, metal aluminates, zirconium silicate, zirconium aluminate, other suitable P-type work function materials, combinations of these, or the like. Additionally, the P-type work function metal layer 314P may be deposited using a deposition process such as ALD, CVD, or the like, although any suitable deposition process may be used.

After the formation of the gate dielectric layer 110N and the gate electrode layer 112N shown in FIGS. 24A and 24B. The source/drain contacts 130-1 and 130-2 discussed above may be further formed to pass through the ILD layer 126, the CESLs 124, and portions of the source/drain features 118N to be in contact with and electrically connected to the source/drain features 118N, as shown in FIGS. 1A and 1B. Furthermore, the dielectric layer 128 is formed under the substrate 102, and then the source/drain contact 130-3 discussed above may be further formed to pass through the dielectric layer 128, the substrate 102, and a portion of the source/drain feature 118P to be in contact with and electrically connected to the source/drain features 118P, as shown in FIGS. 1A and 1B. Therefore, the workpiece 200 is formed into the semiconductor device 100 with CFETs 100A and 100B.

The embodiments disclosed herein relate to semiconductor structures and their manufacturing methods, and more particularly to methods and semiconductor structures including CFETs constructed by a NFET with thinner nanostructures and a PFET with wider nanostructures. Furthermore, the present embodiments provide one or more of the following advantages. The NFET with thinner nanostructures in the CFET have better gate control and the PFET with wider nanostructures in the CFET have better mobility and higher on-current, thereby improving the performance of the CFET.

Thus, one of the embodiments of the present disclosure describes a semiconductor structure that includes a first transistor and a second transistor. The first transistor includes first nanostructures spaced apart from each other in a Z-direction and first source/drain features on opposite sides of the first nanostructures in an X-direction. The second transistor includes second nanostructures spaced apart from each other in the Z-direction and second source/drain features on opposite sides of the second nanostructures in the X-direction. The second nanostructures are over the first nanostructures. The second source/drain features are over the first source/drain features. The semiconductor structure further includes a gate structure wrapping around the first nanostructures and the second nanostructures. A thickness of middle portions of the first nanostructures is greater than a thickness of middle portions of the second nanostructures.

In some embodiments, a difference between the thickness of the middle portions of the first nanostructures and the thickness of the middle portions of the second nanostructures is in a range from about 0.5 nm to about 5 nm.

In some embodiments, the thickness of the middle portion of a bottommost nanostructure of the first nanostructures is greater than the thickness of the middle portion of other nanostructure of the first nanostructures.

In some embodiments, a thickness of side portions of a bottommost nanostructure of the first nanostructures is greater than a thickness of side portions of other nanostructure of the first nanostructures.

In some embodiments, the thickness of the middle portion of a topmost nanostructure of the second nanostructures is greater than the thickness of the middle portion of other nanostructure of the second nanostructures.

In some embodiments, a thickness of side portions of a topmost nanostructure of the second nanostructures is greater than a thickness of side portions of other nanostructure of the second nanostructures.

In some embodiments, a thickness of side portions of the first nanostructures minus the thickness of the middle portions of the first nanostructures is smaller than a thickness of side portions of the second nanostructures minus the thickness of the middle portions of the second nanostructures.

In some embodiments, the thickness of the side portions of the first nanostructures and the thickness of the side portions of the second nanostructures are the same.

In some embodiments, the thickness of the side portions of the first nanostructures is greater than the thickness of the side portions of the second nanostructures.

In some embodiments, a width of the middle portions of the first nanostructures in a Y-direction is greater than a width of the middle portions of the second nanostructures in the Y-direction.

In another of the embodiments, discussed is a semiconductor structure including a first transistor and a second transistor. The first transistor includes first nanostructures over a substrate and first source/drain features attached to the first nanostructures in an X-direction. The first nanostructures are spaced apart from each other in a Z-direction. The second transistor includes second nanostructures over the first nanostructures and second source/drain features attached to the second nanostructures in the X-direction. The second nanostructures are spaced apart from each other in the Z-direction. The second source/drain features are over the first source/drain features. The semiconductor structure further includes a gate structure wrapping around the first nanostructures and the second nanostructures. A first difference between a thickness of middle portions of the first nanostructures and a thickness of side portions of the first nanostructures is smaller a second difference between a thickness of middle portions of the second nanostructures and a thickness of side portions of the second nanostructures.

In some embodiments, a difference between the first difference and the second difference is in a range from about 0.5 nm to about 5 nm.

In some embodiments, the semiconductor structure further includes bottom dielectric layers under and in contact with the second source/drain features.

In some embodiments, the semiconductor structure further includes a source/drain contact under and in contact with one of the first source/drain features. The thickness of the middle portion of a bottommost nanostructure of the first nanostructures is greater than the thickness of the middle portion of other nanostructure of the first nanostructures.

In some embodiments, the semiconductor structure further includes a source/drain contact over and in contact with one of the second source/drain features. The thickness of the middle portion of a topmost nanostructure of the second nanostructures is greater than the thickness of the middle portion of other nanostructure of the second nanostructures.

In some embodiments, a width of the middle portions of the first nanostructures in a Y-direction is greater than a width of the middle portions of the second nanostructures in the Y-direction.

In some embodiments, a width of a base portion protruded from the substrate under the first nanostructures and the second nanostructures in the Y-direction is greater than the width of the middle portions of the first nanostructures in the Y-direction.

In yet another of the embodiments, discussed is a method for manufacturing a semiconductor structure that includes forming a fin over a substrate in a Z-direction. The fin includes first semiconductor layers and second semiconductor layers alternately stacked. The second semiconductor layers include a first group and a second group over the first group. The method further includes forming a dummy gate structure over the fin; forming first source/drain features on opposite sides of the dummy gate structure and attached to the first group of the second semiconductor layers in an X-direction; and forming second source/drain features on opposite sides of the dummy gate structure and attached to the second group of the second semiconductor layers in the X-direction. The second source/drain features are over the first source/drain features. The method further includes removing the dummy gate structure and the first semiconductor layers in the fin to form a gate trench; forming a first work function metal in the gate trench to wrap around the first group of the second semiconductor layers; trimming the second group of the second semiconductor layers; and forming a second work function metal in the gate trench to wrap around the second group of the second semiconductor layers.

In some embodiments, the method further includes forming the first semiconductor layers and the second semiconductor layers over the substrate, wherein a thickness of the first group of the second semiconductor layers is greater than a thickness of the second group of the second semiconductor layers; and patterning the first semiconductor layers and the second semiconductor layers into the fin.

In some embodiments, the method further includes forming source/drain trenches on opposite sides of the dummy gate structure and in the fin; forming bottom dielectric layers in the source/drain trenches; forming the first source/drain features over the bottom dielectric layers and in the source/drain trenches; and forming the second source/drain features over the first source/drain features and in the source/drain trenches.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first transistor, comprising:
first nanostructures spaced apart from each other in a Z-direction; and
first source/drain features on opposite sides of the first nanostructures in an X-direction; and
a second transistor, comprising:
second nanostructures spaced apart from each other in the Z-direction, wherein the second nanostructures are over the first nanostructures; and
second source/drain features on opposite sides of the second nanostructures in the X-direction, wherein the second source/drain features are over the first source/drain features; and
a gate structure wrapping around the first nanostructures and the second nanostructures,
wherein a thickness of middle portions of the first nanostructures is greater than a thickness of middle portions of the second nanostructures.

2. The semiconductor structure of claim 1, wherein a difference between the thickness of the middle portions of the first nanostructures and the thickness of the middle portions of the second nanostructures is in a range from about 0.5 nm to about 5 nm.

3. The semiconductor structure of claim 1, wherein the thickness of the middle portion of a bottommost nanostructure of the first nanostructures is greater than the thickness of the middle portion of other nanostructure of the first nanostructures.

4. The semiconductor structure of claim 1, wherein a thickness of side portions of a bottommost nanostructure of the first nanostructures is greater than a thickness of side portions of other nanostructure of the first nanostructures.

5. The semiconductor structure of claim 1, wherein the thickness of the middle portion of a topmost nanostructure of the second nanostructures is greater than the thickness of the middle portion of other nanostructure of the second nanostructures.

6. The semiconductor structure of claim 1, wherein a thickness of side portions of a topmost nanostructure of the second nanostructures is greater than a thickness of side portions of other nanostructure of the second nanostructures.

7. The semiconductor structure of claim 1, wherein a thickness of side portions of the first nanostructures minus the thickness of the middle portions of the first nanostructures is smaller than a thickness of side portions of the second nanostructures minus the thickness of the middle portions of the second nanostructures.

8. The semiconductor structure of claim 7, wherein the thickness of the side portions of the first nanostructures and the thickness of the side portions of the second nanostructures are the same.

9. The semiconductor structure of claim 7, wherein the thickness of the side portions of the first nanostructures is greater than the thickness of the side portions of the second nanostructures.

10. The semiconductor structure of claim 1, wherein a width of the middle portions of the first nanostructures in a Y-direction is greater than a width of the middle portions of the second nanostructures in the Y-direction.

11. A semiconductor structure, comprising:
a first transistor, comprising:
first nanostructures over a substrate, wherein the first nanostructures are spaced apart from each other in a Z-direction; and
first source/drain features attached to the first nanostructures in an X-direction; and
a second transistor, comprising:
second nanostructures over the first nanostructures, wherein the second nanostructures are spaced apart from each other in the Z-direction; and
second source/drain features attached to the second nanostructures in the X-direction, wherein the second source/drain features are over the first source/drain features; and
a gate structure wrapping around the first nanostructures and the second nanostructures,
wherein a first difference between a thickness of middle portions of the first nanostructures and a thickness of side portions of the first nanostructures is smaller a second difference between a thickness of middle portions of the second nanostructures and a thickness of side portions of the second nanostructures.

12. The semiconductor structure of claim 11, wherein a difference between the first difference and the second difference is in a range from about 0.5 nm to about 5 nm.

13. The semiconductor structure of claim 11, further comprising:
bottom dielectric layers under and in contact with the second source/drain features.

14. The semiconductor structure of claim 11, further comprising:
a source/drain contact under and in contact with one of the first source/drain features,
wherein the thickness of the middle portion of a bottommost nanostructure of the first nanostructures is greater than the thickness of the middle portion of other nanostructure of the first nanostructures.

15. The semiconductor structure of claim 11, further comprising:
a source/drain contact over and in contact with one of the second source/drain features,
wherein the thickness of the middle portion of a topmost nanostructure of the second nanostructures is greater than the thickness of the middle portion of other nanostructure of the second nanostructures.

16. The semiconductor structure of claim 11, a width of the middle portions of the first nanostructures in a Y-direction is greater than a width of the middle portions of the second nanostructures in the Y-direction.

17. The semiconductor structure of claim 16, wherein a width of a base portion protruded from the substrate under the first nanostructures and the second nanostructures in the Y-direction is greater than the width of the middle portions of the first nanostructures in the Y-direction.

18. A method for manufacturing a semiconductor structure, comprising:
forming a fin over a substrate in a Z-direction, wherein the fin comprises first semiconductor layers and second semiconductor layers alternately stacked, wherein the second semiconductor layers comprise a first group and a second group over the first group;
forming a dummy gate structure over the fin;
forming first source/drain features on opposite sides of the dummy gate structure and attached to the first group of the second semiconductor layers in an X-direction;
forming second source/drain features on opposite sides of the dummy gate structure and attached to the second group of the second semiconductor layers in the X-direction, wherein the second source/drain features are over the first source/drain features;
removing the dummy gate structure and the first semiconductor layers in the fin to form a gate trench;
forming a first work function metal in the gate trench to wrap around the first group of the second semiconductor layers;
trimming the second group of the second semiconductor layers; and
forming a second work function metal in the gate trench to wrap around the second group of the second semiconductor layers.

19. The method of claim 18, further comprising:
forming the first semiconductor layers and the second semiconductor layers over the substrate, wherein a thickness of the first group of the second semiconductor layers is greater than a thickness of the second group of the second semiconductor layers; and
patterning the first semiconductor layers and the second semiconductor layers into the fin.

20. The method of claim 18, further comprising:
forming source/drain trenches on opposite sides of the dummy gate structure and in the fin;
forming bottom dielectric layers in the source/drain trenches;
forming the first source/drain features over the bottom dielectric layers and in the source/drain trenches; and
forming the second source/drain features over the first source/drain features and in the source/drain trenches.
